(19) United States
(12) Patent Application Publication
(10) Pub. No.: US 2026/0118749 A1
(43) Pub. Date: Apr. 30, 2026

(54) MASK ASSEMBLY AND MANUFACTURING METHOD OF THE SAME

(71) Applicant: Samsung Display Co., LTD., Yongin-si, Gyeonggi-do (KR)

(72) Inventors: JONGHWAN LEE, Yongin-si (KR); YONG JUN PARK, Yongin-si (KR)

(21) Appl. No.: 19/273,922

(22) Filed: Jul. 18, 2025

(30) Foreign Application Priority Data
Oct. 30, 2024 (KR) 10-2024-0151124

(51) Int. Cl. G03F 1/80

(52) U.S. Cl. CPC G03F 1/80

(57) ABSTRACT

A mask assembly includes a wafer in which cell openings are defined, an upper layer which is disposed on the top surface of the wafer and in which upper openings respectively overlapping the cell openings are defined, first pattern parts disposed on the upper layer to be spaced apart from each other in a plan view and respectively overlapping the cell openings, a first lower layer disposed on the rear surface of the wafer, and a second lower layer disposed under the first lower layer. Pattern openings are defined in each of the first pattern parts.

This application claims priority to Korean Patent Application No. 10-2024-0151124, filed on Oct. 30, 2024, and all the benefits accruing therefrom under 35 U.S.C. § 119, the content of which in its entirety is herein incorporated by reference.

### BACKGROUND

### 1. Field

The disclosure herein relates to a mask assembly and a manufacturing method of the same, and more particularly, to a mask assembly with which deposition process reliability is improved, and a manufacturing method of the same.

### 2. Description of the Related Art

A display device includes a plurality of pixels, and each of the pixels includes a driving element such as a transistor and a display element such as an organic light-emitting diode. The display element may be formed by stacking an electrode and a light-emitting pattern on a substrate.

The light-emitting pattern is formed through patterning with a mask assembly having a hole defined therein so that the light-emitting pattern is formed in a region. Since repetitive use of production facilities is desired to produce relatively large quantities of display panels, research is desired to provide production facilities with improved reliability.

### SUMMARY

The disclosure provides a mask assembly with which deposition process reliability is improved by preventing a warpage phenomenon from occurring in the mask assembly.

The disclosure also provides a manufacturing method of a mask assembly in which a warpage phenomenon is prevented.

An embodiment of the inventive concept provides a mask assembly including a wafer in which cell openings penetrating a top surface and a rear surface are defined, an upper layer which is disposed on the top surface of the wafer and in which upper openings respectively overlapping the cell openings are defined, first pattern parts disposed on the upper layer to be spaced apart from each other in a plan view and respectively overlapping the cell openings, a first lower layer disposed on the rear surface of the wafer, and a second lower layer disposed under the first lower layer. Pattern openings are defined in each of the first pattern parts.

In an embodiment, the upper layer may include one among silicon oxide (SiOx), silicon nitride (SiNx), silicon oxynitride (SiON), and metal nitride, and the first pattern parts may include another one.

In an embodiment, at least a portion of a top surface of the upper layer may be exposed from the first pattern parts, and the wafer may include silicon.

In an embodiment, in a plan view, a separation distance between the first pattern parts next (adjacent) to each other may be about 2 millimeters (mm) to about 5 mm.

In an embodiment, the wafer may have a circular shape in a plan view, the mask assembly may further include dummy pattern parts disposed on the upper layer and spaced apart from the first pattern parts in a plan view, and the dummy pattern parts next (adjacent) to each other may be disposed symmetrically to each other in the plan view with respect to a virtual line crossing a center of the wafer.

In an embodiment, the dummy pattern parts and the first pattern parts may include a same material and the dummy pattern parts may not overlap the cell openings.

In an embodiment, the mask assembly may further include (2-1)-th pattern parts disposed on the upper layer and extending in a first direction, and (2-2)-th pattern parts disposed on the upper layer and extending in a second direction crossing the first direction, where the first pattern parts may be respectively disposed between the (2-1)-th pattern parts next (adjacent) to each other and the (2-2)-th pattern parts next (adjacent) to each other.

In an embodiment, the (2-1)-th pattern parts and the (2-2)-th pattern parts may be spaced apart from the first pattern parts by intervals.

In an embodiment, the mask assembly may further include (2-1)-th pattern parts disposed between the first pattern parts next (adjacent) in a first direction and arranged along a second direction crossing the first direction, and (2-2)-th pattern parts disposed between the first pattern parts next (adjacent) to each other in the second direction and arranged along the first direction.

In an embodiment, the mask assembly may further include (2-3)-th pattern parts disposed between the (2-1)-th pattern parts next (adjacent) to each other and the (2-2)-th pattern parts next (adjacent) to each other, and have an ‘X’ shape.

In an embodiment, the mask assembly may further include (2-1)-th pattern parts extending in a first direction and disposed between the first pattern parts next (adjacent) to each other in a second direction crossing the first direction, and (2-2)-th pattern parts extending in the second direction and spaced apart from each other in the second direction with the (2-1)-th pattern parts respectively interposed therebetween.

In an embodiment, first lower openings respectively overlapping the cell openings in the plan view may be defined in the first lower layer, and second lower openings respectively overlapping the first lower openings in the plan view may be defined in the second lower layer.

In an embodiment, each of the cell openings may have a width becoming smaller toward the rear surface of the wafer and the top surface of the wafer.

In an embodiment, the pattern openings may overlap the cell openings, and ends of the first pattern parts may overlap the upper layer in the plan view.

In an embodiment, the top surface of the wafer may directly contact the upper layer, and a top surface of the upper layer may directly contact a first pattern part of the first pattern parts.

In an embodiment of the inventive concept, a method for manufacturing a mask assembly includes providing a wafer, forming an upper layer on a top surface of the wafer and forming a first lower layer on a rear surface of the wafer, forming a pattern layer on a top surface of the upper layer and forming a second lower layer on a rear surface of the first lower layer, etching the pattern layer to form a pattern part including first pattern parts which are, in a plan view, spaced apart from each other and in which pattern openings defined, respectively, etching the first and second lower layers and defining lower openings, and etching the wafer toward the top surface from the rear surface and defining cell openings respectively overlapping the first pattern parts.

In an embodiment, the forming the upper layer and the forming the first lower layer may be performed at the same time through a single process, and the forming the pattern layer and the forming the second lower layer may be performed at the same time through a single process.

In an embodiment, the defining the lower openings may include etching the second lower layer toward a top surface from a rear surface and defining a second lower opening, and etching the first lower layer toward a top surface from the rear surface and defining a first lower opening.

In an embodiment, the method may further include etching the pattern layer to form a second pattern part spaced apart from the first pattern parts in a plan view, where the forming the first pattern parts and the forming the second pattern parts may be performed at the same time through a single process.

In an embodiment, the defining the cell openings may be performed through wet etching, and each of the cell openings may have a width becoming smaller toward the rear surface of the wafer and the top surface of the wafer.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view of an embodiment of an electronic apparatus according to the inventive concept;

FIG. 2 is a view illustrating an embodiment of use of an electronic apparatus according to the inventive concept;

FIG. 3 is an exploded perspective view of an embodiment of an electronic apparatus according to the inventive concept, in which a portion of an electronic apparatus is disassembled;

FIG. 4 is a cross-sectional view of an embodiment of a deposition device according to the inventive concept;

FIG. 5A is a plan view of an embodiment of a mask assembly according to the inventive concept;

FIG. 5B is an enlarged plan view of region AA′ in FIG. 5A;

FIG. 6 is a cross-sectional view of a mask assembly according to Comparative Example;

FIG. 7 is a cross-sectional view of the mask assembly taken along line I-I′ of FIG. 6;

FIG. 8 is a block diagram of an embodiment of a mask assembly manufacturing method according to the inventive concept;

FIGS. 9A to 9H illustrate an embodiment of operations of a mask assembly manufacturing method according to inventive concept, respectively;

FIG. 10 is a plan view of an embodiment of a mask assembly according to the inventive concept;

FIG. 11 is an enlarged plan view of region BB′ in FIG. 10;

FIG. 12 is a cross-sectional view of the mask assembly taken along line II-II′ of FIG. 11;

FIG. 13 is a block diagram of an embodiment of a mask assembly manufacturing method according to the inventive concept;

FIGS. 14A and 14B illustrate an embodiment of operations of a mask assembly manufacturing method according to inventive concept, respectively;

FIG. 15 is an enlarged plan view of an embodiment of a portion of a mask assembly according to the inventive concept;

FIG. 16 is an enlarged plan view of an embodiment of a portion of a mask assembly according to the inventive concept;

FIG. 17 is an enlarged plan view of an embodiment of a portion of a mask assembly according to the inventive concept;

FIG. 18 is a plan view of an embodiment of a mask assembly according to the inventive concept;

FIG. 19 is a plan view of a display panel manufactured using a mask assembly illustrated in FIG. 4;

FIG. 20 is a cross-sectional view of one pixel illustrated in FIG. 19; and

FIG. 21 is a view for describing a deposition process using the deposition device illustrated in FIG. 4.

### DETAILED DESCRIPTION

In the inventive concept, various modifications may be made and various forms may be applied, and illustrative embodiments will be illustrated in the drawings and described in detail in the text. However, this is not intended to limit the inventive concept to a specific disclosure form, it should be understood to include all changes, equivalents, and substitutes included in the spirit and scope of the inventive concept.

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element from another element. For instance, a first element discussed below could be termed a second element without departing from the scope of the inventive concept. Similarly, a second element could be termed a first element. In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept are described with reference to the drawings.

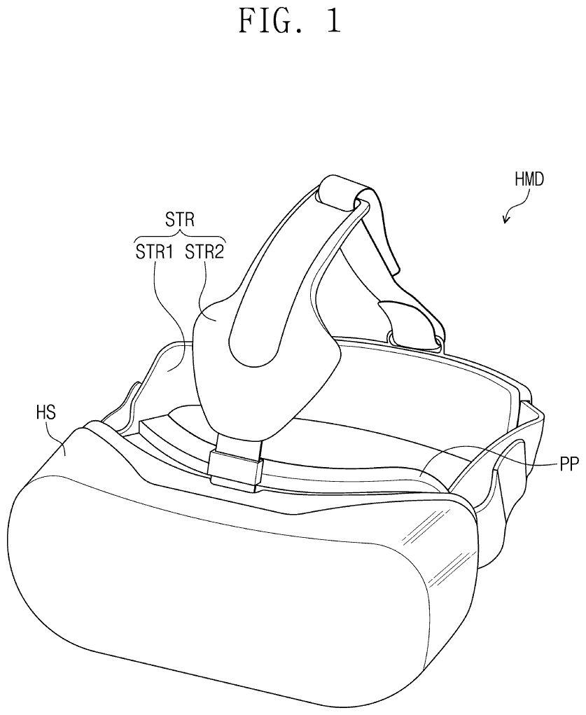

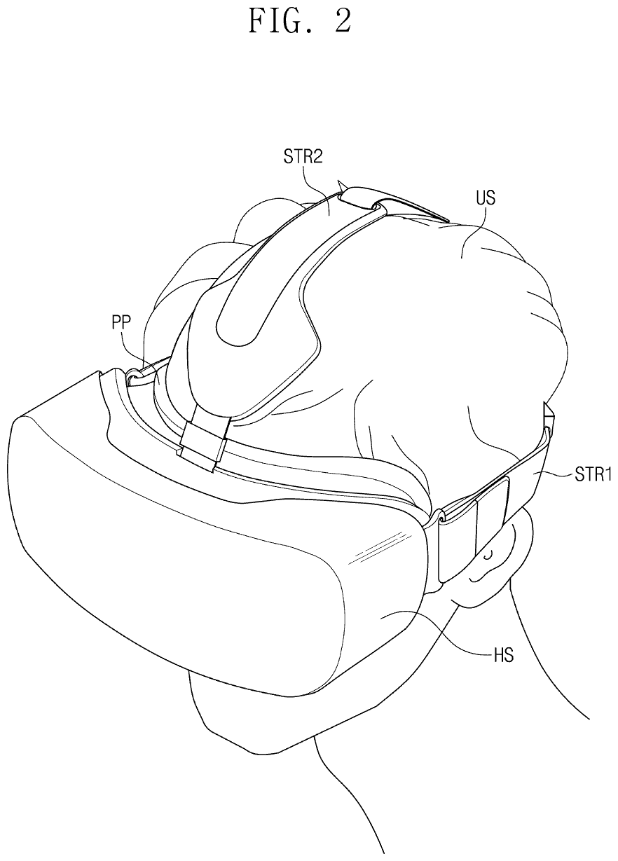

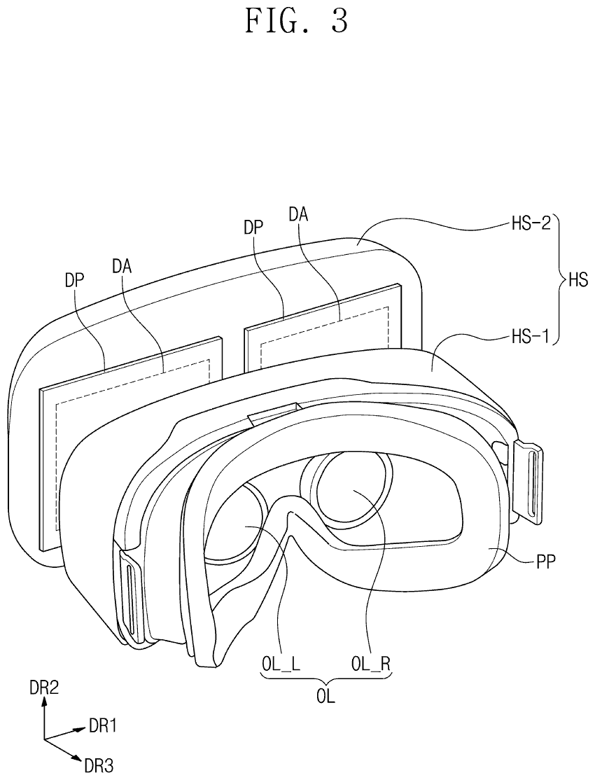

FIG. 1 is a perspective view of an embodiment of an electronic apparatus according to the inventive concept. FIG. 2 is a view illustrating an embodiment of use of an electronic apparatus according to the inventive concept. FIG. 3 is an exploded perspective view of an embodiment of an electronic apparatus according to the inventive concept, in which a portion of an electronic apparatus is disassembled.

Referring to FIGS. 1 to 3, an electronic apparatus HMD may be an apparatus activated in response to an electrical signal. In an embodiment, the electronic apparatus HMD may be a mobile phone, a foldable mobile phone, a laptop, a television, a tablet computer, a car navigation unit, a game console, or a wearable apparatus, for example. The wearable apparatus may be an apparatus worn on a user's body and may include a head mounted display for rendering extended reality (“XR”).

FIG. 1 illustrates a head mounted display in an embodiment of the electronic apparatus HMD. In this embodiment, the electronic apparatus HMD may be a display device worn on the head of a user US. The electronic apparatus HMD may provide images while actual peripheral vision of a user US is blocked. A user US wearing the electronic apparatus HMD may immerse oneself into the virtual reality more easily.

The electronic apparatus HMD may include a body HS, a strap STR, a cushion PP, and a display panel DP. Although not illustrated additionally, the electronic apparatus HMD may include various sensors, cameras, or the like.

The body HS may be worn on the head of a user US. The display panel DP for displaying images, an acceleration sensor (not illustrated), etc., may be accommodated inside the body HS. An acceleration sensor may detect movements of a user US and transfer a signal to the display panel DP. Accordingly, the display panel DP may provide images corresponding to changes in a user US's gaze. Thus, a user US may experience a virtual reality similar to the actual reality.

In addition to the components disclosed above, components with various functions may be accommodated in the body HS. The body HS may be also referred to as a housing, a case, or the like. In an embodiment, an operation unit (not illustrated) for adjusting volume, brightness of a screen, or the like may be additionally disposed outside the body HS, for example. The operation unit may be provided as a physical button, or in a form of a touch sensor or the like. Also, a proximity sensor (not illustrated) which determines whether a user US is wearing the electronic apparatus may be accommodated in the body HS. In addition, an external display panel may be additionally disposed on the body HS.

The body HS may be separated into a body part HS-1 and a cover part HS-2. FIG. 3 illustrates the form in which the body part HS-1 and the cover part HS-2 are separated, but the inventive concept is not limited thereto. In an embodiment, the body part HS-1 and the cover part HS-2 may be provided in an integral form and may not be separated from each other, for example.

The display panels DP may be disposed between the body part HS-1 and the cover part HS-2. The display panels DP may each provide images through a display region DA. FIG. 3 illustrates an embodiment in which an image for the left eye and an image for the right eye are respectively provided by the display panels DP separated from each other, but the inventive concept is not limited thereto. In an embodiment, an image for the left eye and an image for the right eye may be displayed by a single display panel, for example. The display panels DP may be driven by individual driving units. However, the inventive concept is not limited thereto, and the display panels DP may be driven by a single driving unit.

The display panels DP generate images corresponding to input image data. The display panels DP may be an organic light-emitting display panel, an inorganic light-emitting display panel, an organic-inorganic light-emitting display panel, a quantum dot display panel, a micro-light-emitting diode (“LED”) display panel, a nano-LED display panel, or a liquid crystal display panel. In this embodiment, the case where the display panels DP are organic light-emitting display panels is described in an embodiment, but the inventive concept is not limited thereto.

The strap STR may be coupled with the body HS and allow a user US to wear the body HS easily. The strap STR may include a main strap STR1 and an upper strap STR2.

The main strap STR1 may be worn around the head circumference of a user US. The main strap STR1 may fix the body HS to a user US so that the body HS is brought into close contact with the head of the user US. The upper strap STR2 may connect the body HS and the main strap STR1 along the top portion of the head of a user US. The upper strap STR2 may prevent the body HS from sliding down. Also, the upper strap STR2 may disperse the weight of the body HS and further improve wearing sensation of a user US.

FIG. 1 illustrates that the main strap STR1 and the upper strap STR2 are in a length-adjustable form, but the inventive concept is not limited thereto. In an embodiment, in another embodiment, the main strap STR1 and the upper strap STR2 may have elasticity and the length-adjustable portion may be omitted, for example.

As long as being capable of fixing the body HS to a user US, the strap STR may be changed into various forms in addition to the forms disclosed in FIGS. 1 and 2. In another embodiment of the inventive concept, the upper strap STR2 may be omitted, for example. In addition, in another embodiment of the inventive concept, the strap STR may be changed into various forms such as a helmet coupled with the body HS, eyeglass temples coupled with the body HS, or the like.

The cushion PP may be disposed between the body HS and the head of a user US. The cushion PP may include or consist of a material that is freely changeable in shape. In an embodiment, the cushion PP may include or consist of a polymer resin (e.g., polyurethane, polycarbonate, polypropylene, and polyethylene), or may include or consist of a sponge obtained by foaming liquid rubber, a urethane-based material, or an acrylic-based material, for example. However, the inventive concept is not limited thereto.

The cushion PP may enable the body HS to be brought into close contact with a user US and improve the wearing sensation of a user US. The cushion PP may be detached from the body HS. In another embodiment of the inventive concept, the cushion PP may be omitted.

An optical system OL may be disposed inside the body part HS-1 of the body HS. The optical system OL may enlarge images provided from the display panels DP. The display panels DP may respectively display images in a third direction DR3 through the display region DA parallel to a first direction DR1 and a second direction DR2 crossing the first direction DR1. The optical system OL may be arranged to be spaced apart from the display panels DP in the third direction DR3. The optical system OL may be disposed between the display panels DP and the eyes of a user US. The optical system OL may include a right eye optical system OL_R and a left eye optical system OL_L. The left eye optical system OL_L may enlarge an image and provide the enlarged image to the right pupil of a user US, and the right eye optical system OL_R may enlarge an image and provide the enlarged image to the left pupil of a user US.

The left eye optical system OL_L and the right eye optical system OL_R may be arranged to be spaced apart from each other in the first direction DR1. A distance between the right eye optical system OL_R and the left eye optical system OL_L may be adjusted to correspond to a distance between the eyes of a user US. Moreover, a distance between the optical system OL and the display panels DP may be adjusted depending on the eyesight of a user US.

The optical system OL may be a convex aspherical lens. In an embodiment, the optical system OL may be a pancake lens, for example, but an embodiment of the inventive concept is not particularly limited thereto. In this embodiment, it is described as an example that the left eye optical system OL_L and the right eye optical system OL_R are each composed of a single lens, but the inventive concept is not limited thereto. In an embodiment, the left eye optical system OL_L and the right eye optical system OL_R may each include a plurality of lenses, for example.

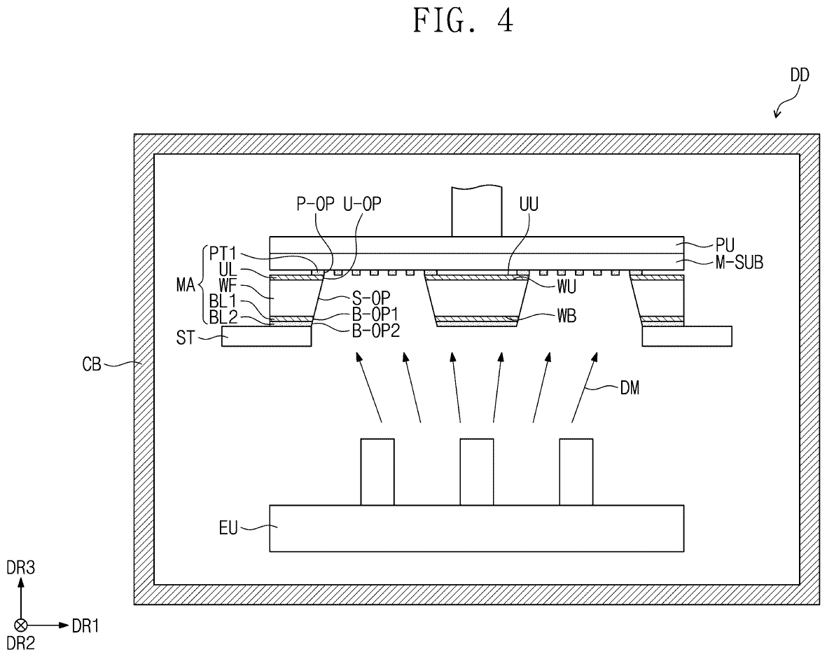

In this embodiment, since the display panels DP are disposed substantially close to the eyes of a user US, it is desired to make the display panels have ‘high resolution’ compared to typical display panels. A ‘warpage phenomenon’ may be reduced in a mask assembly MA (refer to FIG. 4) according to the inventive concept, and deposition reliability may be maintained even in a manufacturing process for a high-resolution display panel.

Also, according to a mask assembly manufacturing method according to the inventive concept, a mask assembly MA (refer to FIG. 4) having a structure capable of maintaining deposition reliability even in a manufacturing process for a high-resolution display panel may be provided. Hereinafter, structural characteristics of the mask assembly MA (refer to FIG. 4) and each operation for the manufacturing method of the mask assembly MA (refer to FIG. 4) will be described with reference to the drawings.

FIG. 4 is a cross-sectional view of an embodiment of a deposition device according to the inventive concept.

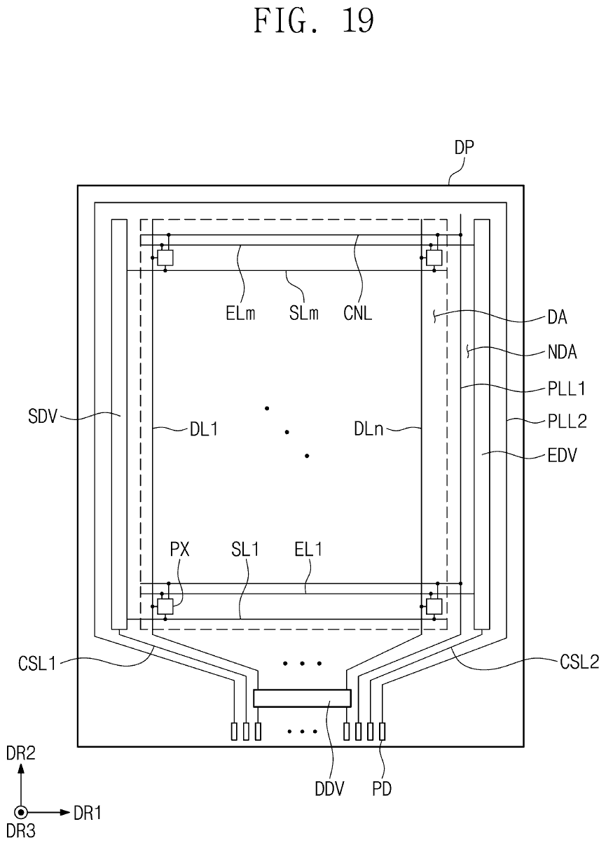

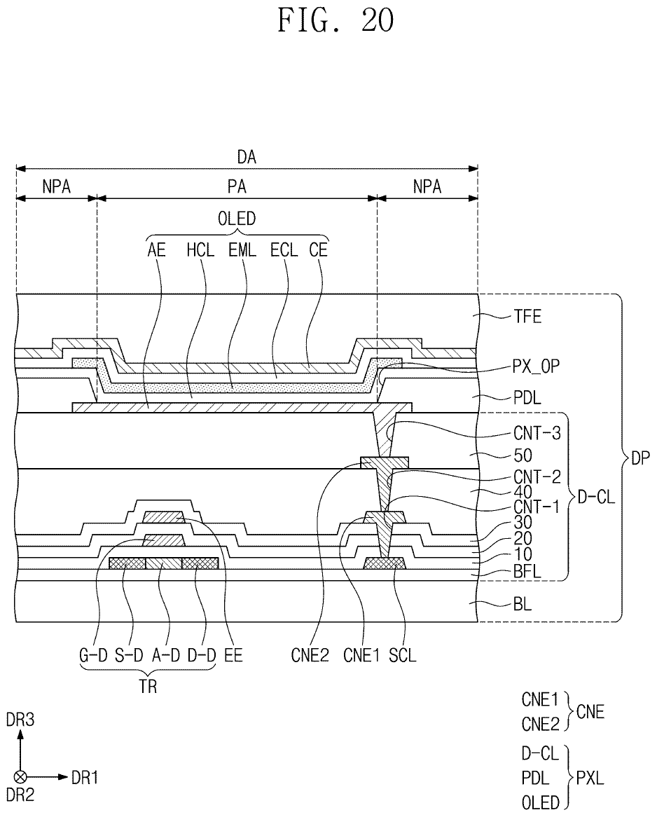

A deposition device DD in an embodiment of the inventive concept may be used in forming at least some of the functional layers included in a display panel DP (refer to FIG. 19) to be described later. In an embodiment, the deposition device DD may be used in a deposition process of a light-emitting layer EML (refer to FIG. 20), for example.

Referring to FIG. 4, the deposition device DD may include a chamber CB, a fixing unit PU, a deposition unit EU, a mask assembly MA, and a stage ST. The deposition device DD in an embodiment of the inventive concept may further include additional mechanical devices to implement an inline system.

The chamber CB may include a floor surface, a ceiling surface, and side walls which provide an internal space, the side walls connecting the floor surface and the ceiling surface. The floor surface of the chamber CB may be parallel to a plane defined by a first direction DR1 and a second direction DR2, and a normal direction of the floor surface of the chamber CB may be parallel to a third direction DR3. In this specification, the wording “in a plan view” may be set based on a plane parallel to the plane defined by the first direction DR1 and the second direction DR2.

The fixing unit PU, the deposition unit EU, the mask assembly MA, and the stage ST may be disposed in the internal space of the chamber CB. In addition, a target substrate M-SUB may be disposed in the internal space of the chamber CB.

A sealed space may be formed inside the chamber CB. Accordingly, the condition of a deposition to be performed inside the chamber CB may be set to a vacuum condition.

Although not illustrated separately, the chamber CB may have at least one gate. The chamber CB may be opened and closed through the gate. The mask assembly MA and the target substrate M-SUB may enter and exit through the gate of the chamber CB.

The fixing unit PU may be disposed above the deposition unit EU inside the chamber CB. The fixing unit PU may function to adhere the mask assembly MA and the target substrate M-SUB to each other.

The fixing unit PU may include a magnetic substance to adhere the mask assembly MA and the target substrate M-SUB. In an alternative embodiment, the fixing unit PU may include an electro-static chuck (“ESC”). The fixing unit PU may apply an attractive force to the mask assembly MA and prevent the mask assembly MA from sagging due to gravity.

FIG. 4 illustrates that the mask assembly MA contacts the target substrate M-SUB. However, the inventive concept is not limited thereto, and the mask assembly MA may not contact the target substrate M-SUB and have a gap therebetween.

Although not illustrated separately, the fixing unit PU may further include a holding part for fixing the target substrate M-SUB. The holding part may function to fix the target substrate M-SUB so that the target substrate does not move during the deposition process. In an embodiment, a groove part in which the target substrate M-SUB is detachable may be defined in the holding part, for example.

The target substrate M-SUB may be an object to be processed on which a deposition material DM is deposited. In an embodiment, the target substrate M-SUB may include a support substrate and a synthetic resin layer disposed on the support substrate and corresponding to a base layer BL (refer to FIG. 20), for example. The support substrate may be removed during a latter part of a manufacturing process of a display panel DP (refer to FIG. 19). Depending on the structure formed through a deposition process, the target substrate M-SUB may include some components of the display panel DP (refer to FIG. 19) formed on the base layer BL (refer to FIG. 20).

The deposition unit EU may be disposed to face the fixing unit PU inside the chamber CB. The deposition unit EU may include a space for accommodating the deposition material DM and at least one nozzle for spraying the deposition material DM. FIG. 4 illustrates an embodiment in which the deposition unit EU includes three nozzles, but the inventive concept is not limited thereto.

The deposition material DM may include an inorganic material, metal, or an organic material which is sublimable or evaporable. The deposition material DM may pass through the mask assembly MA and be deposited on the target substrate M-SUB in a pattern.

The mask assembly MA may be disposed on the stage ST to be described later. The mask assembly MA may be disposed between the deposition unit EU and the target substrate M-SUB. In an embodiment, the mask assembly MA may be detachably fixed to the stage ST, for example. A top surface of the mask assembly MA may face the target substrate M-SUB.

The mask assembly MA may allow the deposition material DM to be deposited in a pattern on the target substrate M-SUB. The mask assembly MA may enable the deposition material DM to selectively pass through in a predetermined region.

The mask assembly MA in an embodiment of the inventive concept may include a wafer WF, an upper layer UL, first pattern parts PT1, a first lower layer BL1, and a second lower layer BL2.

Cell openings S-OP which completely penetrate the wafer in a thickness direction may be defined in the wafer WF. The cell openings S-OP may define a region in which a deposition pattern is formed on the target substrate M-SUB. FIG. 4 illustrates an embodiment in which two cell openings S-OP are defined. A method of forming the cell openings S-OP will be described later.

The wafer WF may include silicon (Si). In an embodiment, the wafer WF may be a “silicon wafer”, for example.

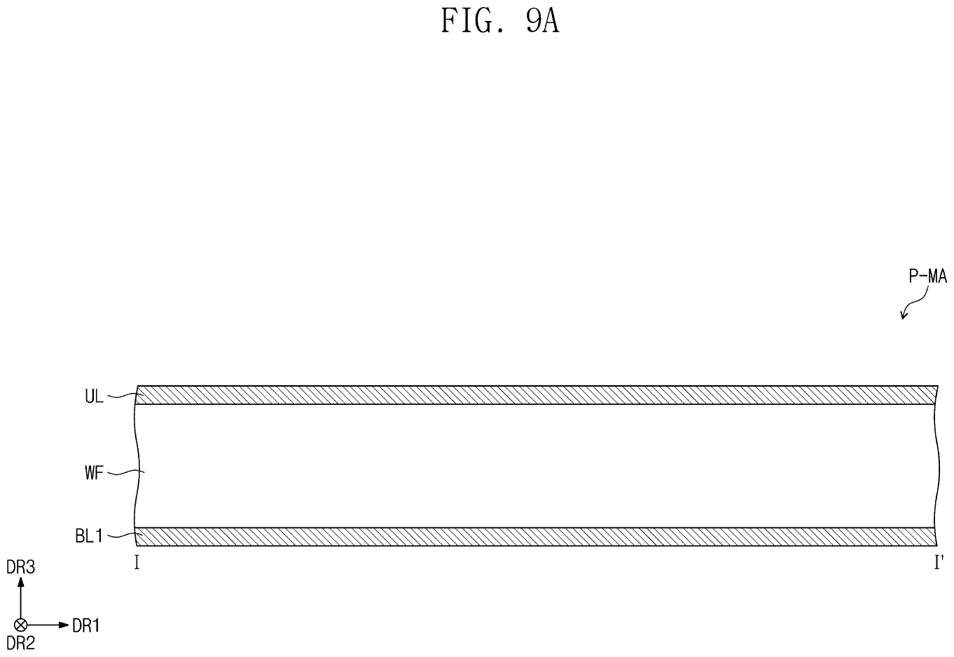

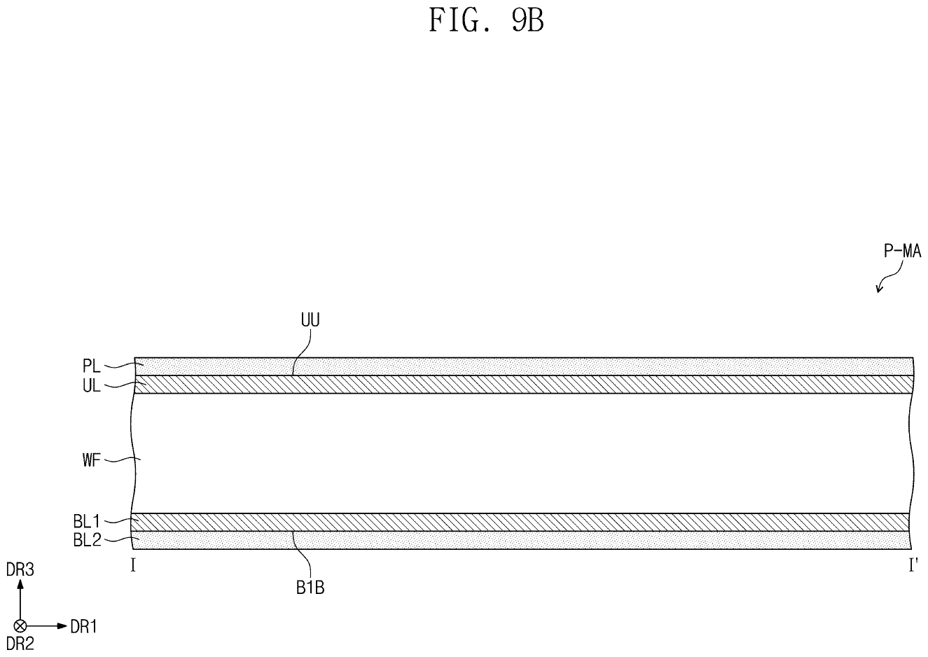

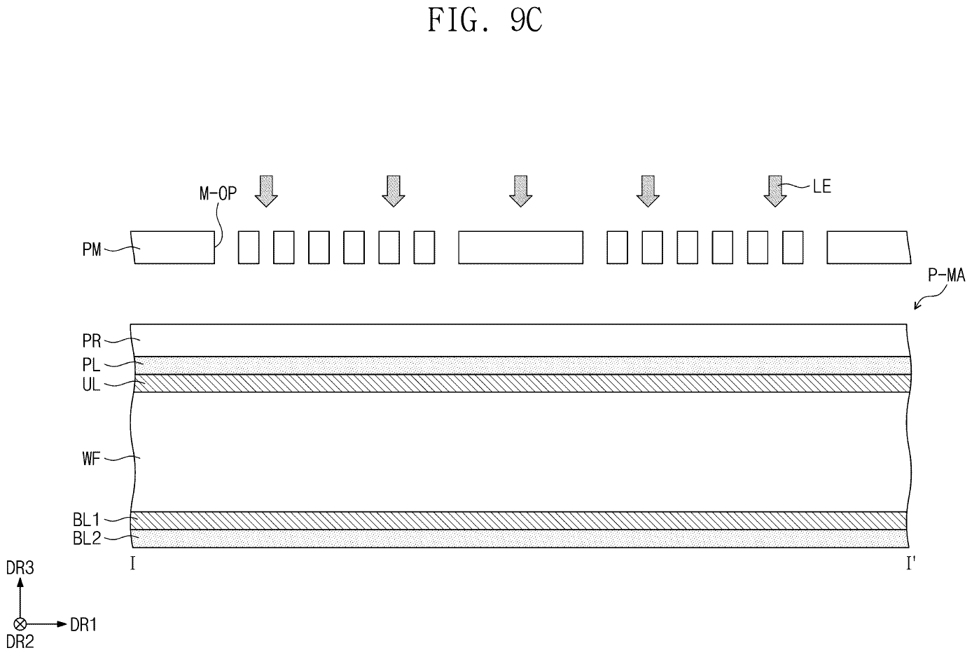

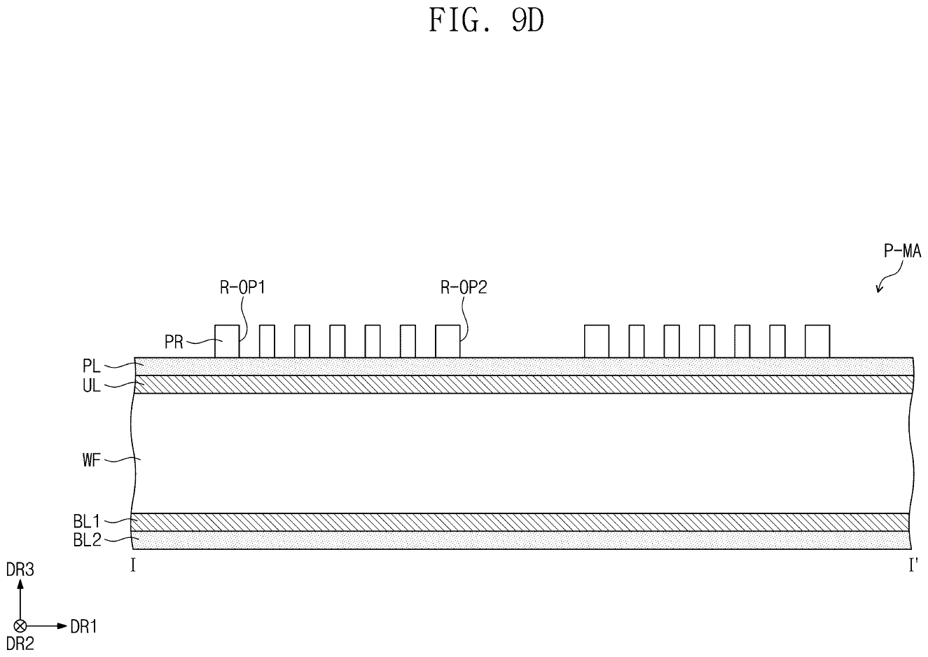

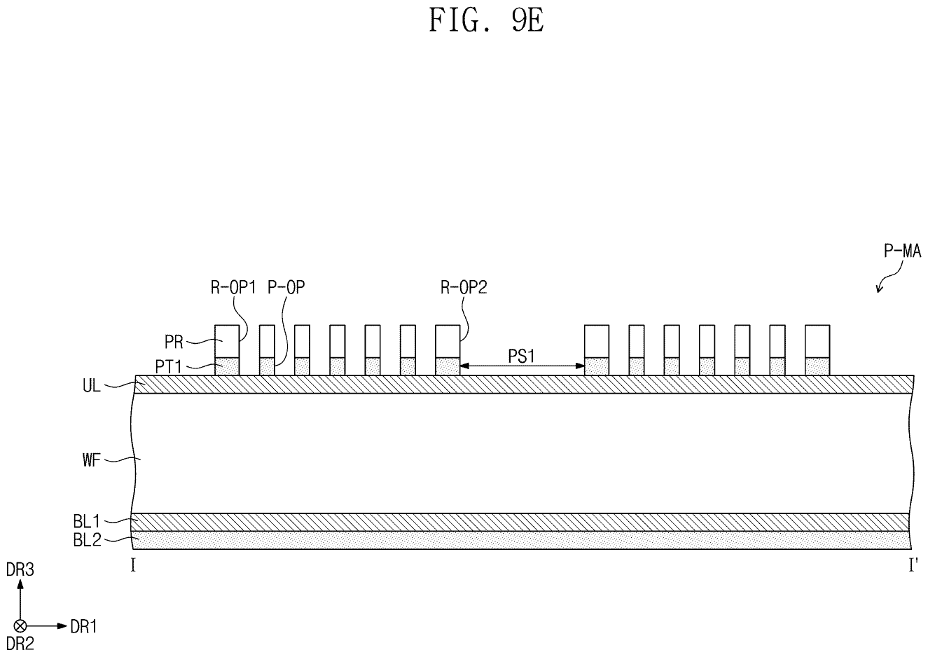

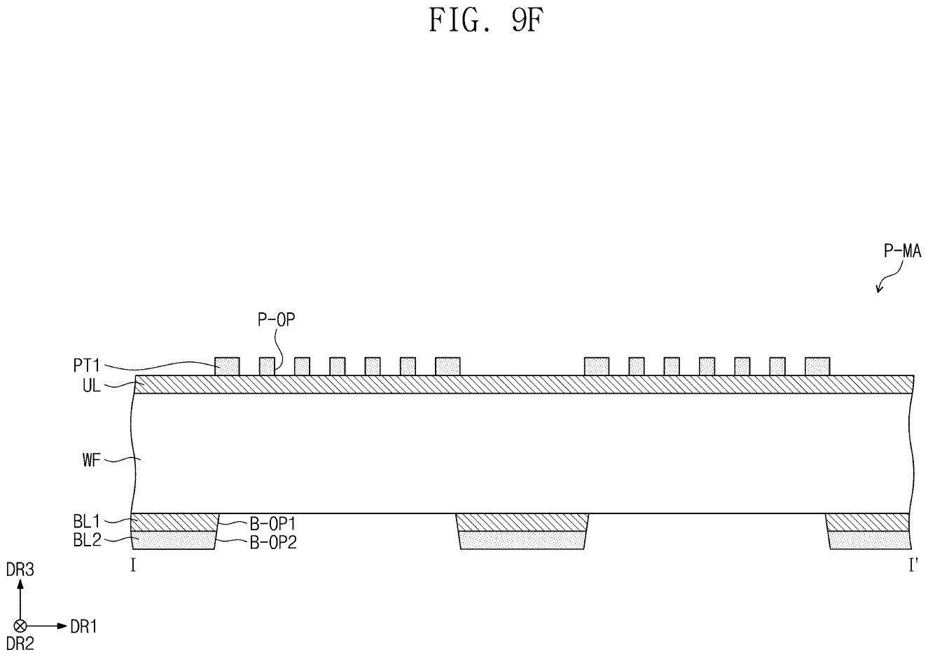

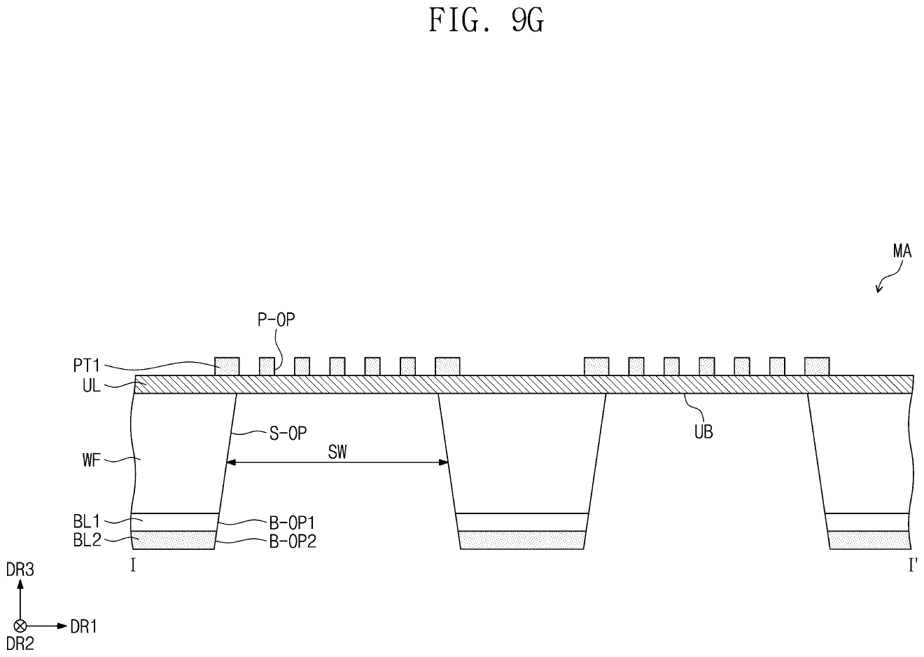

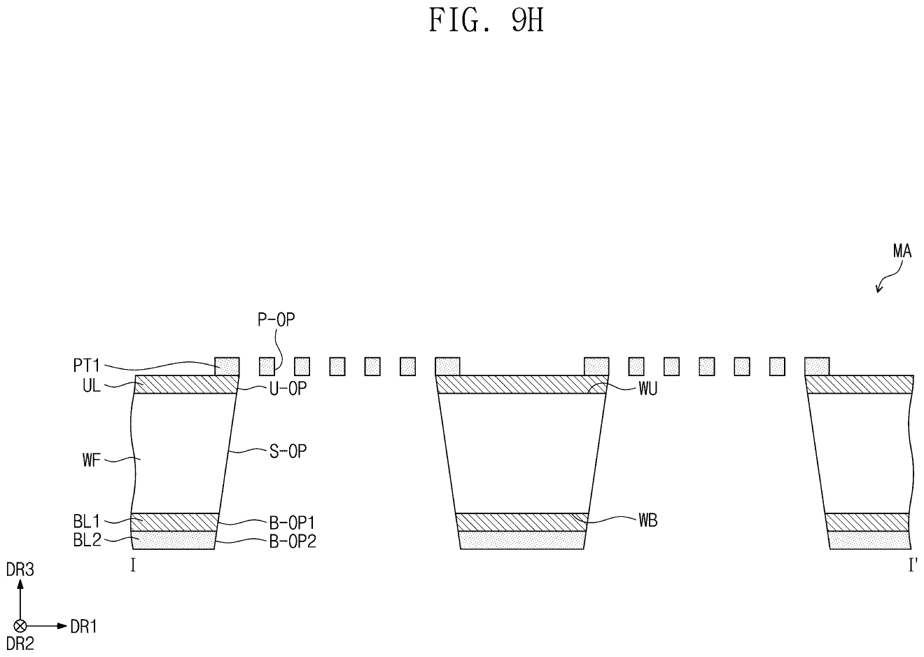

The upper layer UL may be disposed on the wafer WF. The upper layer UL may contact a top surface WU (refer to FIG. 9H) of the wafer WF. In an embodiment, the upper layer UL may be in direct contact with the top surface WU of the wafer WF, for example.

Upper openings U-OP which completely penetrate the upper layer in the thickness direction may be defined in the upper layer UL. The upper openings U-OP and the cell openings S-OP may respectively overlap each other in a plan view.

The first pattern parts PT1 may be disposed on the upper layer UL. The first pattern parts PT1 may contact a top surface UU of the upper layer UL. In an embodiment, the top surface UU of the upper layer UL may be in direct contact with the first pattern parts PT1, for example.

The first pattern parts PT1 may be spaced apart from each other in a plan view with intervals therebetween. FIG. 4 illustrates an embodiment in which two first pattern parts PT1 are arranged to be spaced apart from each other in the first direction DR1.

On a plane, the first pattern parts PT1 and the cell openings S-OP may respectively overlap each other. The first pattern parts PT1 and the upper openings U-OP may respectively overlap each other. Accordingly, pattern openings P-OP may overlap the upper opening U-OP and the cell opening S-OP.

The pattern openings P-OP may be defined in each of the first pattern parts PT1. The pattern openings P-OP may be defined by completely penetrating the first pattern part PT1 in the thickness direction. The pattern openings P-OP may be defined in plurality in a single first pattern part PT1. FIG. 4 illustrates an embodiment in which six pattern openings P-OP are defined in each of the first pattern openings PT1 in a cross-section.

The upper layer UL may include any one among silicon oxide (SiOx), silicon nitride (SiNx), silicon oxynitride (SiON), and metal nitride. In addition, the first pattern parts PT1 may include, among silicon oxide (SiOx), silicon nitride (SiNx), silicon oxynitride (SiON), and metal nitride, another one different from the material of the upper layer UL.

In an embodiment, in this embodiment, the upper layer UL may include silicon oxide (SiOx), and the first pattern parts PT1 may include silicon nitride (SiNx), for example.

The first lower layer BL1 may be disposed on a rear surface WB of the wafer WF.

First lower openings B-OP1 may be defined in the first lower layer BL1. On a plane, the first lower openings B-OP1 and the cell openings S-OP may respectively overlap each other.

The second lower layer BL2 may be disposed under the first lower layer BL1. On a plane, second lower openings B-OP2 and the first lower openings B-OP1 may respectively overlap each other.

The first lower layer BL1 and the upper layer UL may be formed through a single process and may include the same material as each other. The second lower layer BL2 and the first pattern parts PT1 may be formed through a single process and may include the same material as each other. A mask assembly manufacturing method will be described later.

The stage ST may be disposed between the deposition unit EU and the fixing unit PU. The stage ST may be disposed outside a movement path of the deposition material DM provided toward the target substrate M-SUB from the deposition unit EU.

The stage ST may support the mask assembly MA. The stage ST may provide a seating surface on which the mask assembly MA is to be disposed. The seating surface may be parallel to the first direction DR1 and the second direction DR2. In an embodiment, the seating surface of the stage ST may be provided in parallel to the floor surface of the chamber CB.

The deposition material DM may pass through the lower openings B-OP1 and B-OP2, the cell opening S-OP, the upper opening U-OP, and the pattern opening P-OP and be deposited onto a deposition surface of the target substrate M-SUB to correspond to a shape of the pattern opening P-OP, but the deposition material may be blocked in other regions.

Here, when a “warpage phenomenon” occurs in the mask assembly MA, the mask assembly MA may not be adhered to the target substrate M-SUB, thereby resulting in a reduction in the reliability of a deposition process. However, the mask assembly MA according to the inventive concept may prevent the warpage phenomenon of the mask by adjusting the tensile stresses formed in an upper portion and in a lower portion of the mask assembly MA to be offset. This will be described later.

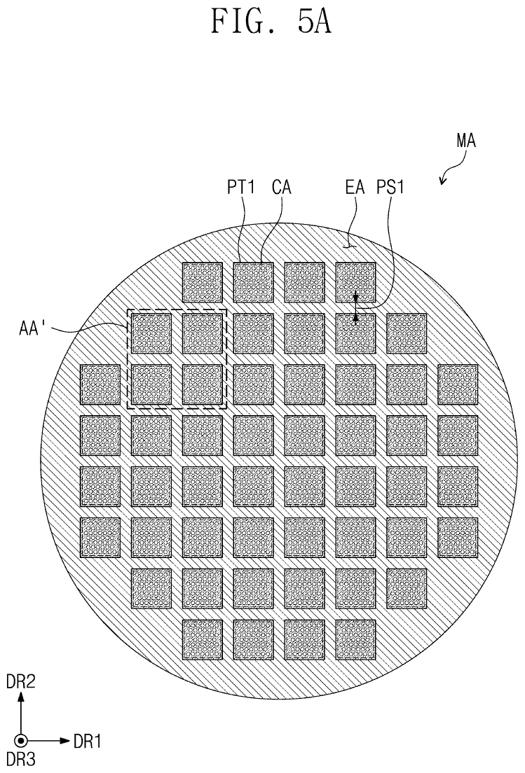

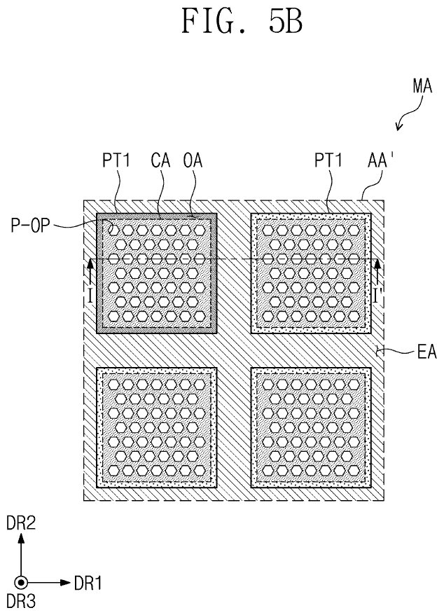

FIG. 5A is a plan view of an embodiment of the mask assembly according to the inventive concept. FIG. 5B is an enlarged plan view of region AA′ in FIG. 5A.

Referring to FIG. 5A, in this embodiment, the wafer WF may have a circular shape in a plan view. However, the inventive concept is not limited thereto. In an embodiment, the mask assembly MA may have a polygonal shape, for example.

On a plane, cell regions CA and a peripheral region EA surrounding the cell regions CA in a plan view may be defined in the mask assembly MA. The cell regions CA may correspond to the cell openings S-OP (refer to FIG. 4). FIG. 5 illustrates an embodiment in which 52 cell regions CA are arranged in the first direction DR1 and the second direction DR2, but an embodiment of the inventive concept is not limited to what is illustrated. An arrangement method and the number of the cell regions CA may differ from what is illustrated.

The first pattern parts PT1 may be arranged to be spaced apart from each other with intervals therebetween. In this specification, a distance between the first pattern parts PT1 may be referred to as a “first distance PS1”. This will be described later.

FIG. 5 illustrates an embodiment in which 52 first pattern parts PT1 are arranged in the first direction DR1 and the second direction DR2. An arrangement of the first pattern parts PT1 is not limited to what is illustrated.

Referring to FIG. 5B, the first pattern parts PT1 may respectively overlap the cell regions CA. A planar area of each of the first pattern parts PT1 may be greater than a planar area of each of the cell regions CA. That is, a portion of the first pattern part PT1 may overlap the cell region CA and another portion may overlap the top surface UU (refer to FIG. 4) of the upper layer UL (refer to FIG. 4).

For the convenience of explanation, in FIG. 5B, the regions in which the first pattern parts PT1 respectively overlap the cell regions CA are illustrated in dotted quadrilateral shape, and one of “overlapping regions OA” where each of the first pattern parts PT1 overlap the upper layer UL (refer to FIG. 4) is shown by dark hatching.

FIG. 5B illustrates that hexagonal pattern openings P-OP are defined in each of the first pattern parts PT1 and spaced apart from each other in the first direction DR1, the second direction DR2, and a direction between the first direction DR1 and the second direction DR2. On a plane, the pattern openings P-OP may be defined to overlap the cell region CA.

However, the inventive concept is not limited thereto, and the pattern openings P-OP may be defined to correspond to a location and a shape of a pattern which is to be formed on the target substrate M-SUB.

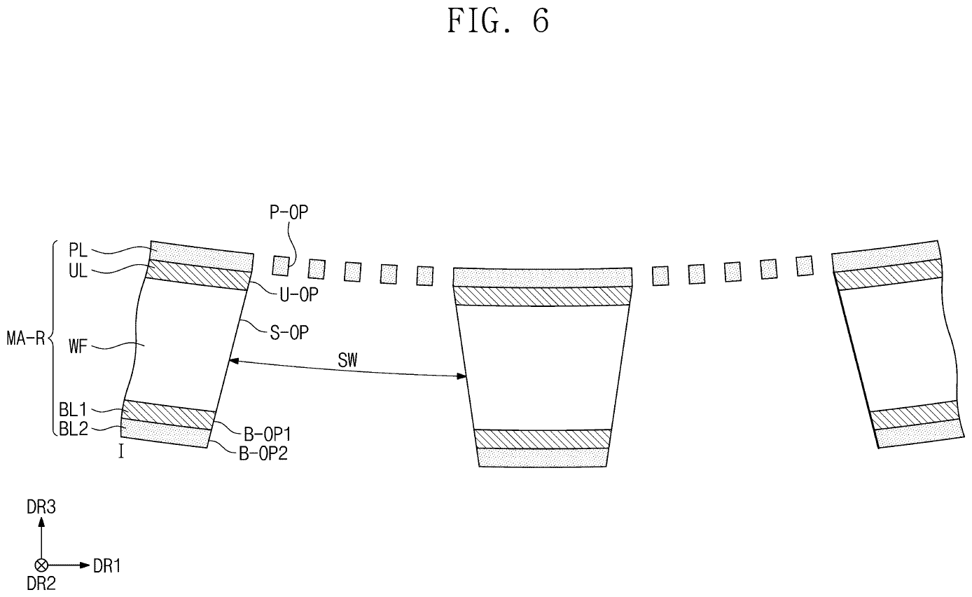

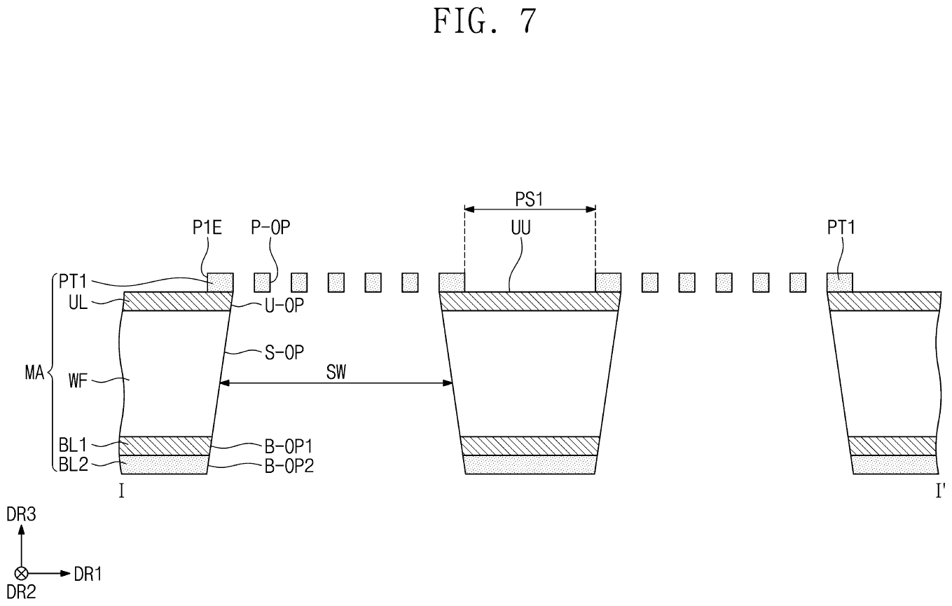

FIG. 6 is a cross-sectional view of a mask assembly according to Comparative Example. FIG. 7 is a cross-sectional view of the mask assembly taken along line I-I′ of FIG. 5B.

A mask assembly MA-R according to Comparative Example may correspond to a typical mask assembly. The mask assembly MA-R according to Comparative Example includes a pattern layer PL having a continuously integrated shape on an upper layer UL.

Accordingly, “tensile stress” may occur due to the consecutive pattern layer PL on a top surface of the mask assembly MA-R according to Comparative Example, thus leading to a structural deformation. In an embodiment, a warpage deformation may occur in the mask assembly according to Comparative Example. FIG. 6 illustrates an embodiment in which the mask assembly MA-R is bent further upwards toward a peripheral portion and deformed to have a “U” shape, for example.

Referring to FIG. 7, the first pattern parts PT1 of the mask assembly MA in an embodiment of the inventive concept may be disposed on the upper layer UL and arranged to be “spaced apart” from each other. In an embodiment, the two first pattern parts PT1 next (adjacent) to each other may be spaced apart from each other with an interval therebetween, for example. In an embodiment, a separation distance PS1 between the two first pattern parts PT1 next (adjacent) to each other in a plan view may be about 2 millimeters (mm) to about 5 mm, for example.

Accordingly, at least a portion of the top surface UU of the upper layer UL may be exposed from the first pattern parts PT1. That is, the first pattern parts PT1 may be spaced apart from each other with intervals therebetween, and at least a portion of the top surface UU of the upper layer UL may be exposed between the first pattern parts PT1. An exposed top surface UU of the upper layer UL may face the target substrate M-SUB (refer to FIG. 4) during the deposition process.

Since the first pattern parts PT1 are arranged to be spaced apart from each other in a plan view, the mask assembly MA in an embodiment of the inventive concept may effectively prevent tensile stress from occurring on the top surface of the mask assembly MA. Accordingly, the warpage phenomenon may be prevented from occurring in the mask assembly MA.

On a plane, ends P1E of the first pattern parts PT1 may overlap the upper layer UL.

In a cross-section, a width SW of each of the cell openings S-OP may become smaller toward the third direction DR3. In an embodiment, the width SW of each of the cell openings S-OP may gradually become smaller toward the third direction DR3, for example.

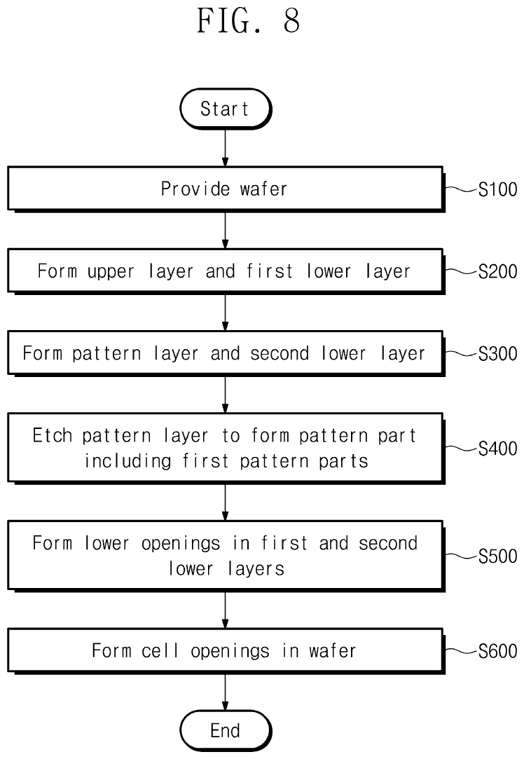

FIG. 8 is a block diagram of an embodiment of a mask assembly manufacturing method according to the inventive concept.

Referring to FIG. 8, the mask assembly manufacturing method in an embodiment of the inventive concept may include an operation S100 of providing a wafer, an operation S200 of forming an upper layer on a top surface of the wafer and forming a first lower layer on a rear surface of the wafer, an operation S300 of forming a pattern layer on a top surface of the upper layer and forming a second lower layer on a rear surface of the first lower layer, an operation S400 of etching the pattern layer to form a pattern part including first pattern parts which are, in a plan view, spaced apart from each other and each have pattern openings defined therein, an operation S500 of etching the first and second lower layers to form lower openings, and an operation S600 of etching the wafer toward the top surface from the rear surface to form cell openings respectively overlapping the first pattern parts.

FIGS. 9A to 9H illustrate, respectively, an embodiment of operations of a mask assembly manufacturing method according to inventive concept.

Hereinafter, with reference to FIGS. 9A to 9G, an embodiment of respective operations of the mask assembly manufacturing method according to inventive concept will be described.

For the convenience of explanation, in this specification, a mask assembly MA that is in a state before completion, during a manufacturing process of the mask assembly MA, will be referred to as a “preliminary mask P-MA”.

Referring to FIG. 9A, a “preliminary mask P-MA” may be provided. The preliminary mask P-MA illustrated in FIG. 9A may be one that has been subjected to the operation S100 of providing a wafer (refer to FIG. 8), and the operation S200 of forming an upper layer on a top surface of the wafer and forming a first lower layer on a rear surface of the wafer (refer to FIG. 8).

Accordingly, the preliminary mask P-MA may include a wafer WF, an upper layer UL formed on a top surface WU of the wafer WF, and a first lower layer BL1 formed on a rear surface of the wafer.

The forming of the upper layer UL and the forming of the first lower layer BL1 may be performed at the same time through a single process.

In this embodiment, the upper layer UL and the first lower layer BL1 may be formed respectively on the top surface and the rear surface WB of the wafer WF by depositing silicon oxide (SiOx) through chemical vapor deposition (“CVD”).

Then, referring to FIG. 9B, the operation S300 (refer to FIG. 8) of forming a pattern layer on a top surface of the upper layer and forming a second lower layer on a rear surface of the first lower layer may be performed.

The forming of the pattern layer PL and the forming of the second lower layer BL2 may be performed at the same time through a single process.

In this embodiment, the pattern layer PL and the second lower layer BL2 may be formed respectively on a top surface and a rear surface of the preliminary mask P-MA by depositing silicon nitride (SiNx) through CVD.

Accordingly, the pattern layer PL formed on a top surface UU of the upper layer UL and a second lower layer BL2 formed on a rear surface B1B of the first lower layer BL1 may be formed symmetrically to each other with a wafer WF therebetween.

In the mask assembly manufacturing process, the tensile stress formed in the top surface of the preliminary mask P-MA and the tensile stress formed in the rear surface may be offset. Accordingly, a warpage phenomenon may be effectively prevented.

Then, referring to FIGS. 9C to 9F, the operation S400 (refer to FIG. 8) of etching the pattern layer PL to form a pattern part may be performed.

In this specification, first pattern parts or second pattern parts included in one mask assembly will be referred to as a “pattern part”.

The operation S400 (refer to FIG. 8) of forming the pattern part may be performed through a photoresist process.

The operation S400 (refer to FIG. 8) of forming the pattern part may include an operation of forming a photosensitive layer, an operation of patterning the photosensitive layer, and an operation of etching a pattern layer.

Referring to FIG. 9C, a photosensitive layer PR may be formed on the pattern layer PL of the preliminary mask P-MA. The photosensitive layer PR may include a photosensitive material. The forming of a photosensitive layer PR may be performed by applying a photosensitive material through spin coating, inkjet, or the like.

Then, the operation of patterning the photosensitive layer PR may be performed. The patterning process of the photosensitive layer PR may be performed by disposing, on the preliminary mask P-MA, a photo mask PM in which photo openings M-OP are defined, and providing light LE.

Then, referring to FIGS. 9D and 9E together, photosensitive openings R-OP1 and R-OP2 penetrating a top surface and a rear surface of the photosensitive layer PR may be defined in the patterned photosensitive layer PR.

The first photosensitive opening R-OP1 may be used in forming a pattern opening P-OP (refer to FIG. 9E) to be described layer, and the second photosensitive opening R-OP2 may be used in forming a separation space between first pattern parts PT1 (refer to FIG. 9E).

The etching of the pattern layer PL may be performed through wet etching or dry etching. The pattern layer PL may be etched and the pattern part may be formed. In this embodiment, the pattern part may include the first pattern parts PT1. The first pattern parts PT1 may be spaced apart from each other with a distance PS1 therebetween.

Although not illustrated separately, the photosensitive layer PR may be removed by wet strip or dry strip.

Then, referring to FIG. 9F, the operation S500 of etching the first and second lower layers to form lower openings may be performed.

The operation S500 of forming the lower openings may include an operation of etching the second lower layer BL2 toward a top surface from a rear surface to form a second lower opening B-OP2, and an operation of etching the first lower layer BL1 toward a top surface from a rear surface to form a first lower opening B-OP1.

In this embodiment, the etching of the second lower layer BL2 may be performed through dry etching, and the etching of the first lower layer BL1 may be performed through wet etching. However, the inventive concept is not limited thereto, and an etching process may be chosen in consideration of the materials forming the lower layers BL1 and BL2.

Then, referring to FIG. 9G, an operation S600 of etching the wafer toward the top surface from the rear surface to form cell openings respectively overlapping the first pattern parts may be performed.

The wafer WF may be etched toward the top surface from the rear surface and cell openings S-OP penetrating the wafer WF in a thickness direction may be formed.

The wafer WF may be etched until a rear surface UB of the upper layer UL is exposed.

The etching may be performed through wet etching. When forming the cell openings S-OP using an etchant, the wafer WF may not be limited to being etched only in the third direction DR3 and may also be partially etched in the first direction DR1 and the second direction DR2. Accordingly, the cell opening S-OP may have a width SW becoming smaller toward the third direction DR3.

Then, referring to FIG. 9H, an operation of forming an upper opening U-OP may be performed. The upper layer UL may be etched toward the top surface from the rear surface. Here, the etching may be performed through wet etching.

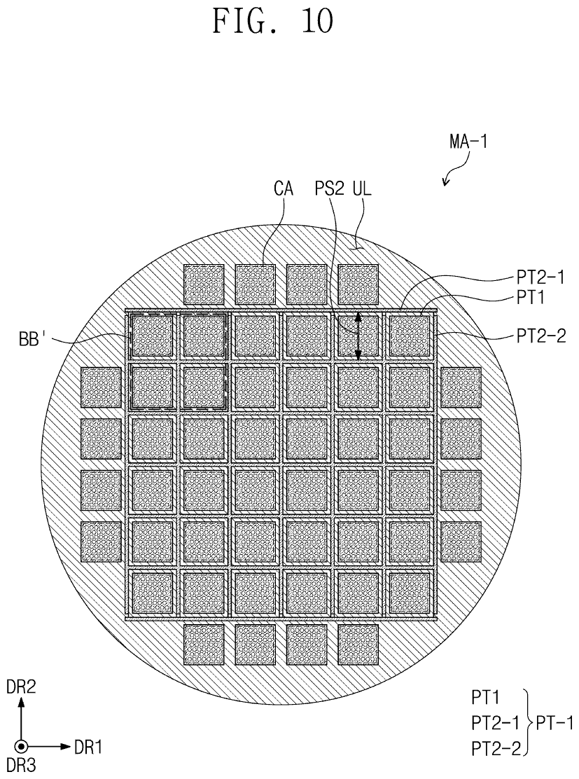

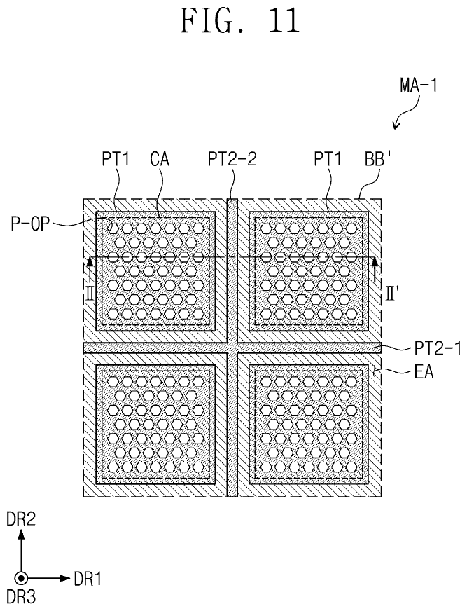

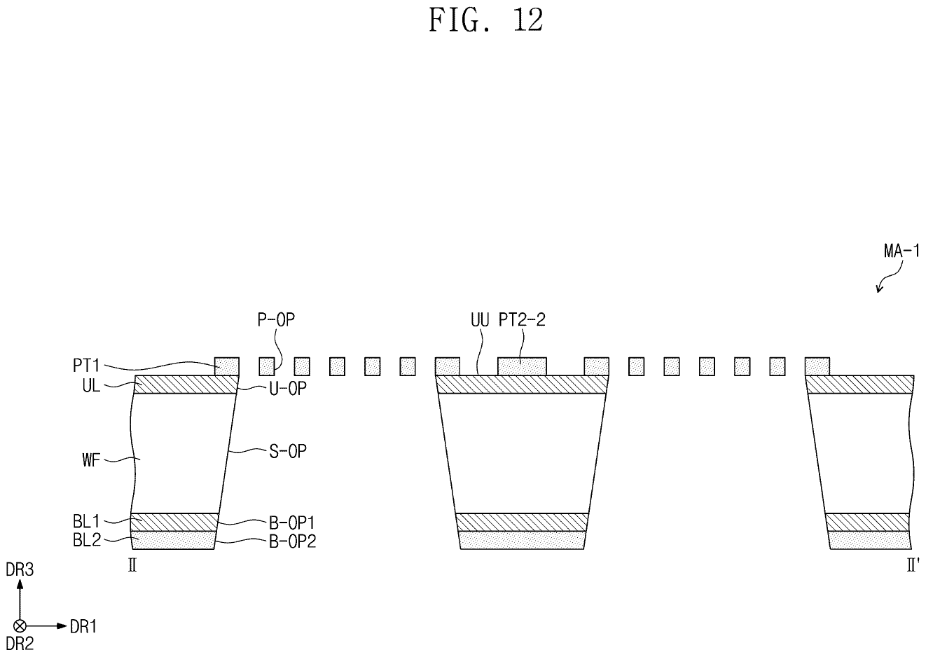

FIG. 10 is a plan view of an embodiment of a mask assembly according to the inventive concept. FIG. 11 is an enlarged plan view of region BB′ in FIG. 10. FIG. 12 is a cross-sectional view of the mask assembly taken along line II-II′ of FIG. 11.

A structure and effect of a mask assembly MA-1 in an embodiment of the inventive concept will be described with reference to FIGS. 10 to 12. Components that are the same as/similar to the components described with reference to FIGS. 4 to 8 are denoted as the same/similar reference numerals or symbols. The duplicated description will be omitted and differences will be mainly explained.

The mask assembly MA-1 in the illustrative embodiment may include a pattern part PT-1. The pattern part PT-1 may include first pattern parts PT1, a (2-1)-th pattern part PT2-1, and a (2-2)-th pattern part PT2-2. That is, the mask assembly MA-1 in the illustrative embodiment may further include the (2-1)-th pattern part PT2-1 and the (2-2)-th pattern part PT2-2 compared to the mask assembly MA described with reference to FIGS. 4 to 8.

The second pattern parts PT2-1 and PT2-2 and the first pattern parts PT1 may be formed at the same time through a single process. That is, the first pattern parts PT1 and the second pattern parts PT2-1 and PT2-2 may include the same material and may be disposed on the upper layer UL (refer to FIG. 4). This will be described later.

The (2-1)-th pattern parts PT2-1 may have a bar shape extending in the first direction DR1 and may be disposed along the second direction DR2.

The (2-2)-th pattern parts PT2-2 may have a bar shape extending in the second direction DR2 and may be disposed along the first direction DR1.

However, the (2-1)-th pattern parts PT2-1 and the (2-2)-th pattern parts PT2-2 are separated for the convenience of explanation, and some of the (2-1)-th pattern parts PT2-1 and some of the (2-2)-th pattern parts PT2-2 may be provided in a continuously integrated shape.

FIG. 10 illustrates an embodiment in which seven (2-1)-th pattern parts PT2-1 and seven (2-2)-th pattern parts PT2-2 are arranged. Referring to FIG. 10, second to sixth (2-1)-th pattern parts PT2-1 disposed along the second direction DR2 and first to seventh (2-2)-th pattern parts PT2-2 disposed along the first direction DR1 may be provided to have a continuously integrated shape and may form a lattice shape.

On a plane, a “lattice cell”, which is a ‘quadrilateral shaped’ space, may be defined between two (2-1)-th pattern parts PT2-1 next (adjacent) to each other and two (2-2)-th pattern parts PT2-2 next (adjacent) to each other. In this specification, a distance between the two (2-1)-th pattern parts PT2-1 next (adjacent) to each other may be referred to as a “second distance PS2”. The first pattern parts PT1 may be respectively disposed in the lattice cells.

FIG. 10 illustrates an embodiment in which 36 lattice cells are defined and a first pattern part PT1 is disposed in each of the lattice cells.

The (2-1)-th pattern part PT2-1 may be disposed between the first pattern parts PT1 next (adjacent) to each other in the second direction DR2, and the (2-2)-th pattern part PT2-2 may be disposed between the first pattern parts PT1 next (adjacent) to each other in the first direction DR1.

As such, since the second pattern parts PT2-1 and PT2-2 are disposed between the first pattern parts PT1, the second pattern parts PT2-1 and PT2-2 may function to ‘block’ the tensile stress formed in an upper portion of the mask assembly MA-1, or may function as a ‘support part’ which prevents a warpage phenomenon of the wafer WF (refer to FIG. 4) itself.

That is, since the mask assembly MA-1 according to the inventive concept further includes the second pattern parts PT2-1 and PT2-2, the tensile stress which may occur in the upper portion of the mask assembly MA-1 may be minutely adjusted.

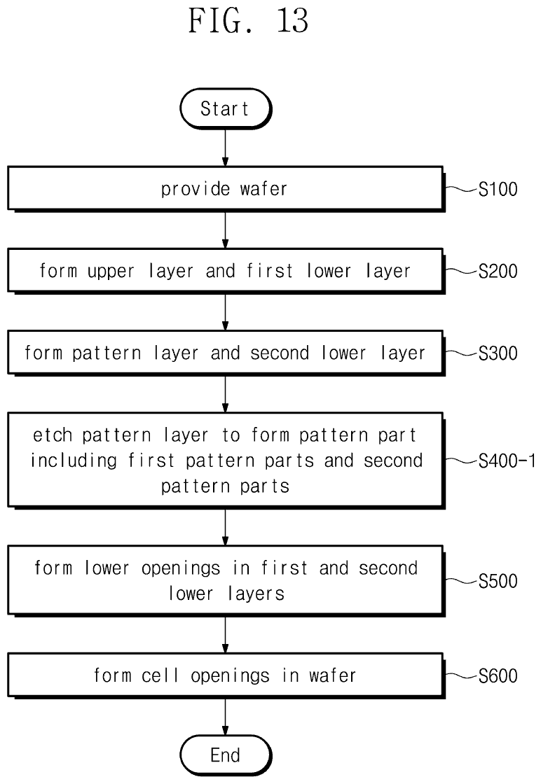

FIG. 13 is a block diagram of an embodiment of a mask assembly manufacturing method according to the inventive concept.

Referring to FIG. 13, the mask assembly manufacturing method in an embodiment of the inventive concept may include an operation S100 of providing a wafer, an operation S200 of forming an upper layer on a top surface of the wafer and forming a first lower layer on a rear surface of the wafer, an operation S300 of forming a pattern layer on a top surface of the upper layer and forming a second lower layer on a rear surface of the first lower layer, an operation S400-1 of etching the pattern layer to form first pattern parts and second pattern parts, an operation S500 of etching the first and second lower layers to form lower openings, and an operation S600 of etching the wafer toward the top surface from the rear surface to form cell openings respectively overlapping the first pattern parts.

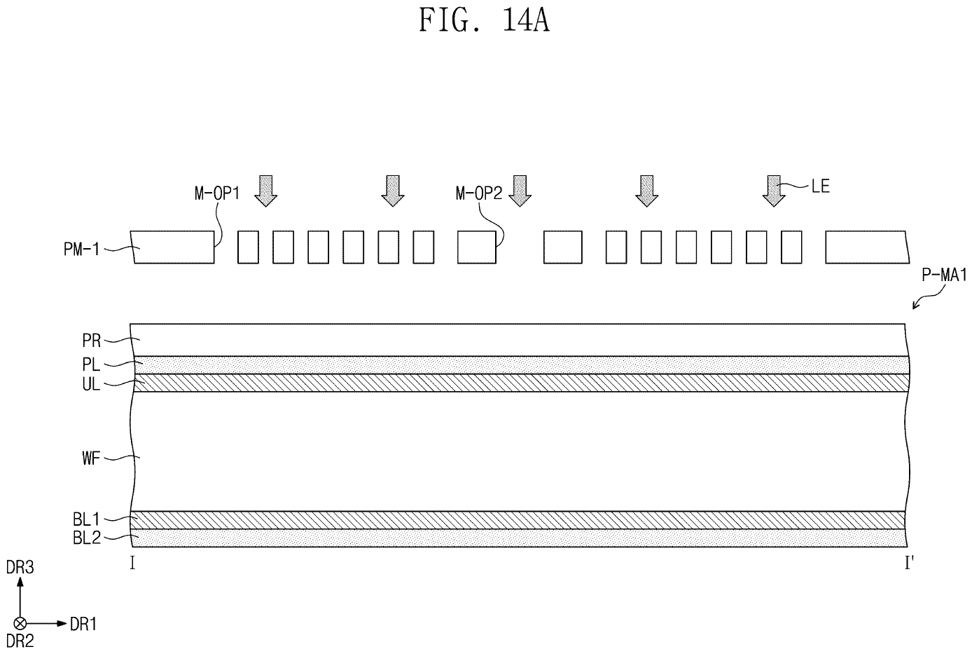

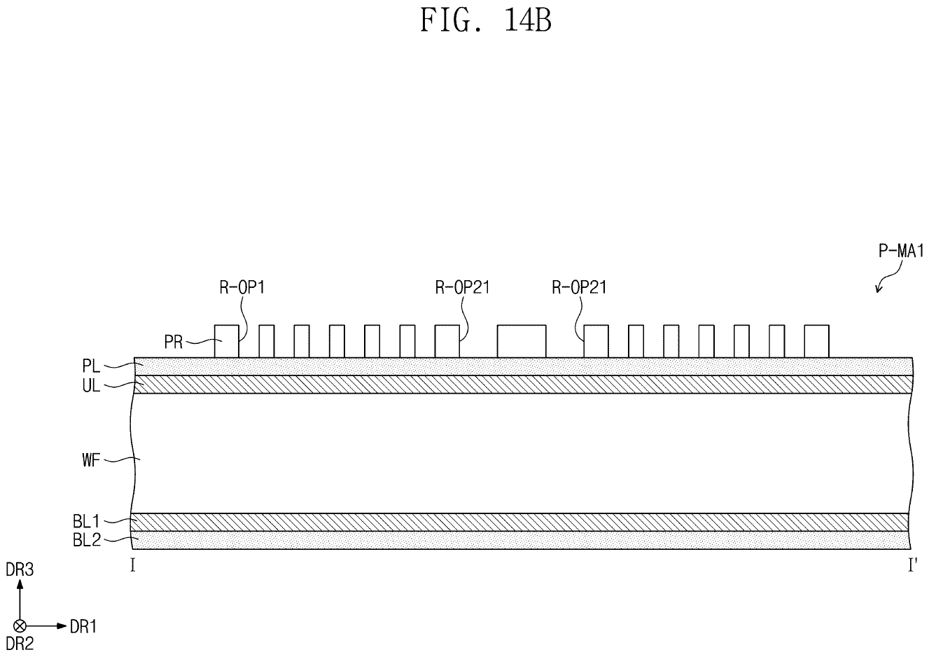

FIGS. 14A and 14B illustrate an embodiment of operations of a mask assembly manufacturing method according to inventive concept, respectively. Components that are the same as/similar to the components described with reference to FIGS. 9A to 9H are denoted as the same/similar reference numerals or symbols. The duplicated description will be omitted and differences will be mainly explained.

A preliminary mask P-MA1 in the illustrative embodiment is a cross section of the preliminary mask P-MA1, on which the operation S100 (refer to FIG. 13) of providing a wafer, the operation S200 (refer to FIG. 13) of forming an upper layer and a first lower layer, and the operation S300 (refer to FIG. 13) of forming a pattern layer and a second lower, as described with reference to FIGS. 9A and 9B, has been performed.

The operation S400-1 (refer to FIG. 13) of forming first pattern parts and second pattern parts may be performed through a photoresist process.

Referring to FIG. 14A, a photosensitive layer PR may be formed on a pattern layer PL of the preliminary mask P-MA1. The photosensitive layer PR may include a photosensitive material. The forming of the photosensitive layer PR may be performed by applying a photosensitive material through spin coating, inkjet, or the like.

Then, an operation of patterning the photosensitive layer PR may be performed. The patterning process of the photosensitive layer PR may be performed by disposing, on the preliminary mask P-MA1, a photo mask PM-1 in which photo openings M-OP1 and M-OP2 are defined, and providing light LE.

Then, referring to FIG. 14B, photosensitive openings R-OP1 and R-OP21 penetrating a top surface and a rear surface of the photosensitive layer PR may be defined in the patterned photosensitive layer PR. The first photosensitive opening R-OP1 may be used in forming a pattern opening P-OP (refer to FIG. 11), and the second photosensitive openings R-OP21 may be used in forming a separation space between the second pattern parts PT2-1 and PT2-2, and the first pattern parts PT1 (refer to FIG. 11).

Then, operations that are the same/similar to the operations explained with reference to FIGS. 9E to 9H are performed, and resultantly the mask assembly MA-1 illustrated in FIGS. 11 and 12 may be manufactured.

That is, in the mask assembly manufacturing method in the illustrative embodiment, not only the first pattern parts but also the second pattern parts may be formed by adjusting the shapes of the photo openings of the photo mask. Accordingly, the mask assembly manufacturing process may become simple, and the costs and time desired for the process may be reduced.

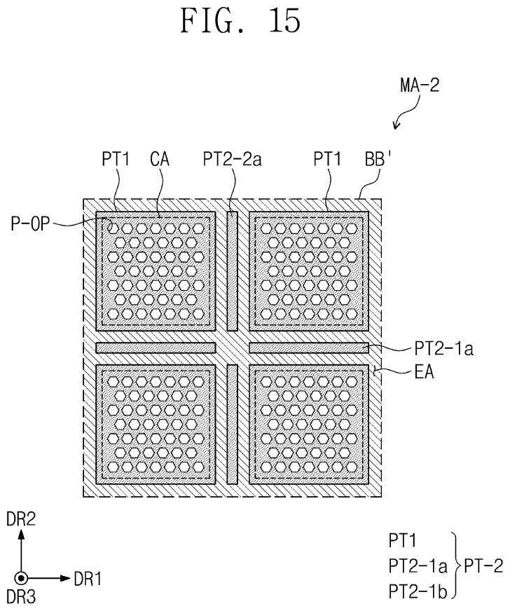

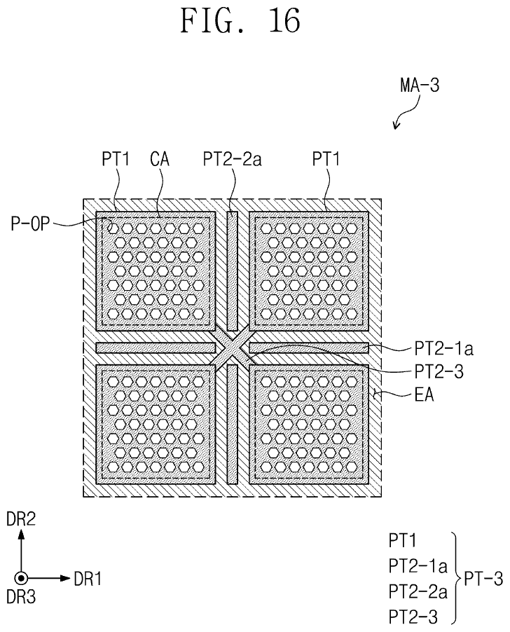

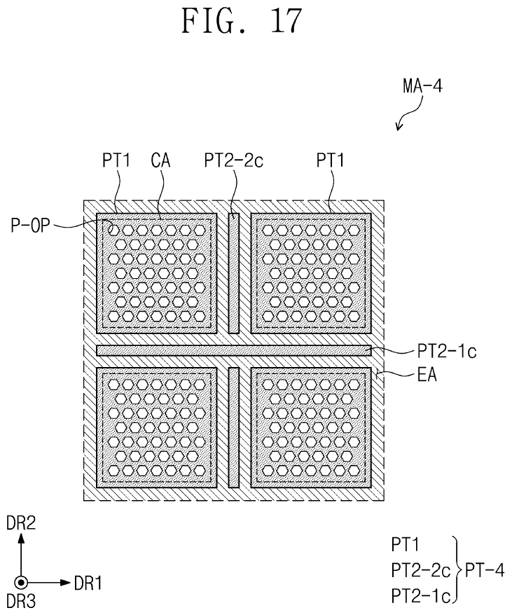

FIG. 15 is an enlarged plan view of an embodiment of a portion of a mask assembly according to the inventive concept. FIG. 16 is an enlarged plan view of an embodiment of a portion of a mask assembly according to the inventive concept. FIG. 17 is an enlarged plan view of an embodiment of a portion of a mask assembly according to the inventive concept.

Hereinafter, various forms of the mask assemblies according to various embodiments will be described with reference to FIGS. 15 to 17.

Referring to FIG. 15, a mask assembly MA-2 in the illustrative embodiment may include a pattern part PT-2. The pattern part PT-2 may include first pattern parts PT1, (2-1)-th pattern parts PT2-1a, and (2-2)-th pattern parts PT2-2a. That is, the mask assembly MA-2 in the illustrative embodiment may further include the (2-1)-th pattern parts PT2-1a and the (2-2)-th pattern parts PT2-2a compared to the mask assembly MA described with reference to FIGS. 4 to 8.

The (2-1)-th pattern parts PT2-1a may each extend along the first direction DR1.

The (2-1)-th pattern parts PT2-1a may be arranged along the first direction DR1.

The (2-1)-th pattern parts PT2-1a may be spaced apart from each other in the first direction DR1 with intervals therebetween.

The (2-1)-th pattern parts PT2-1a may be respectively disposed between the two first pattern parts PT1 next (adjacent) to each other in the second direction DR2.

The (2-2)-th pattern parts PT2-2a may each extend along the second direction DR2.

The (2-2)-th pattern parts PT2-2a may be arranged along the second direction DR2.

The (2-2)-th pattern parts PT2-2a may be spaced apart from each other in the second direction DR2 with intervals therebetween.

The (2-2)-th pattern parts PT2-2a may be respectively disposed between the two first pattern parts PT1 next (adjacent) to each other in the first direction DR1.

Referring to FIG. 16, a mask assembly MA-3 in the illustrative embodiment may include a pattern part PT-3. The pattern part PT-3 may include first pattern parts PT1, (2-1)-th pattern parts PT2-1a, (2-2)-th pattern parts PT2-2a, and (2-3)-th pattern parts PT2-3.

That is, the mask assembly MA-3 in the illustrative embodiment may further include the (2-3)-th pattern parts PT2-3 compared to the mask assembly MA-2 described with reference to FIG. 15.

The (2-3)-th pattern parts PT2-3 may be disposed between the two (2-1)-th pattern parts PT2-1 next (adjacent) to each other and the (2-2)-th pattern parts PT2-2 next (adjacent) to each other.

The (2-3)-th pattern parts PT2-3 may have an alphabet ‘X’ shape in a plan view.

In this embodiment, the (2-3)-th pattern parts PT2-3 may respectively contact the first pattern parts PT1. However, the inventive concept is not limited thereto. In an embodiment, the (2-3)-th pattern parts PT2-3 may be spaced apart from the first pattern parts PT1, for example.

Referring to FIG. 17, a mask assembly MA-4 in the illustrative embodiment may include a pattern part PT-4. The pattern part PT-4 may include first pattern parts PT1, (2-1)-th pattern parts PT2-1c, and (2-2)-th pattern parts PT2-2c.

That is, the mask assembly MA-4 in the illustrative embodiment may further include the (2-1)-th pattern parts PT2-1c and the (2-2)-th pattern parts PT2-2c compared to the mask assembly MA described with reference to FIGS. 4 to 8.

The (2-1)-th pattern parts PT2-1c may have a bar shape extending in the first direction DR1, and may be arranged along the first direction DR1 and the second direction DR2.

The (2-1)-th pattern parts PT2-1c may be spaced apart from each other in the first direction DR1 with intervals therebetween.

The (2-1)-th pattern parts PT2-1c may be respectively disposed between the two (2-2)-th pattern parts PT2-1c next (adjacent) to each other in the second direction DR2.

The (2-2)-th pattern parts PT2-2c may have a bar shape extending in the second direction DR2 and may be arranged along the first direction DR1 and the second direction DR2.

The (2-2)-th pattern parts PT2-2c may be spaced apart from each other in the first direction DR1 and the second direction DR2 with intervals therebetween.

A length of the (2-1)-th pattern part PT2-1c in the first direction DR1 may be different from a length of the (2-2)-th pattern part PT2-2c in the second direction DR2. In an embodiment, a length of the (2-1)-th pattern part PT2-1c in the first direction DR1 may be greater than a length of the (2-2)-th pattern part PT2-2c in the second direction DR2, for example.

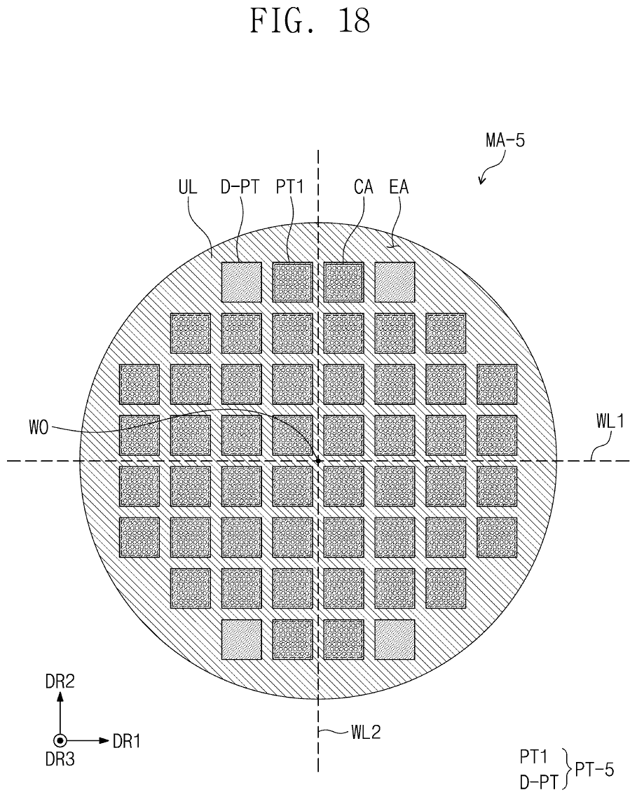

FIG. 18 is a plan view of a mask assembly according to the inventive concept.

Hereinafter, a structure and effect of a mask assembly MA-5 in an embodiment of the inventive concept will be described with reference to FIG. 18. Components that are the same as/similar to the components described with reference to FIGS. 4 to 8 are denoted as the same/similar reference numerals or symbols. The duplicated description will be omitted and differences will be mainly explained.

The mask assembly MA-5 in an embodiment of the inventive concept may further include a dummy pattern part D-PT compared to the mask assembly MA described with reference to FIG. 5. The pattern part PT-5 may include PT1 and the dummy pattern part D-PT.

The dummy pattern part D-PT may be disposed on an upper layer UL. The dummy pattern parts D-PT and first pattern parts PT1 may be spaced apart from each other with intervals therebetween.

Unlike the first pattern parts PT1, the dummy pattern parts D-PT may not define openings defined therein. Also, unlike the first pattern parts PT1, the dummy pattern parts D-PT may not overlap cell openings S-OP.

The dummy pattern part D-PT and the first pattern part PT1 may be formed though the same process, and may include the same material as each other. That is, the dummy pattern parts D-PT may include any one among silicon oxide (SiOx), silicon nitride (SiNx), silicon oxynitride (SiON), and metal nitride.

The dummy pattern part D-PT may be provided in plural.

On a plane, the dummy pattern parts D-PT next (adjacent) to each other may be disposed symmetrically with respect to virtual lines WL1 and WL2 passing through a center WO of a mask assembly MA.

FIG. 18 illustrates an embodiment in which the mask assembly MA-5 includes four dummy pattern parts D-PT.

For the convenience of explanation, the four dummy pattern parts D-PT illustrated in FIG. 18 will be indicated as the dummy pattern parts D-PT respectively disposed in an upper right section, a lower right section, an upper left section, and a lower left section with respect to the center WO of the mask assembly MA-5.

The dummy pattern parts D-PT disposed in the upper section, among the dummy pattern parts D-PT illustrated in FIG. 18, may be symmetric to the dummy pattern parts D-PT disposed in the lower section with respect to the first virtual line WL1. Also, the dummy pattern parts D-PT disposed in the left section may be symmetric to the dummy pattern parts D-PT disposed in the right section with respect to the second virtual line WL2.

In a typical mask assembly, when cell openings are defined asymmetrically in a plan view, the tensile stress is formed asymmetrically in the mask assembly, or weight is imbalanced, thereby resulting in a warpage phenomenon. On the contrary, the mask assembly MA-5 according to the inventive concept includes dummy pattern parts D-PT and may thus effectively prevent a warpage phenomenon which would occur in the mask assembly MA-5.

Also, since the dummy pattern parts D-PT and the first pattern parts PT1 are formed through the same process, a manufacturing process becomes simple, and the costs and time desired for the manufacturing process may be reduced.

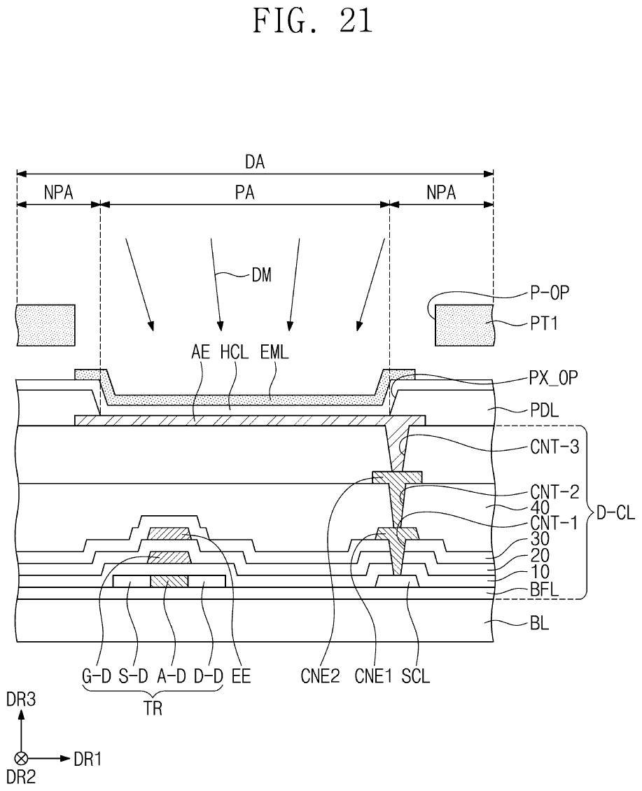

FIG. 19 is a plan view of a display panel manufactured using the mask assembly illustrated in FIG. 4. FIG. 20 is a cross-sectional view of one pixel illustrated in FIG. 19. FIG. 21 is a view for describing a deposition process using the deposition device illustrated in FIG. 4.

FIG. 19 is a plan view of a display panel manufactured using the mask assembly illustrated in FIG. 4.

Referring to FIG. 19, a display panel DP may have a quadrangular shape, e.g., rectangular shape having short sides extending in the first direction DR1 and long sides extending in the second direction DR2, but the shape of the display panel DP is not limited thereto. The display panel DP may include a display region DA and a non-display region NDA surrounding the display region DA.

The display panel DP may be a light-emitting display panel. The display panel DP may be an organic light-emitting display panel or a quantum dot light-emitting display panel. A light-emitting layer of the organic light-emitting display panel may include an organic light-emitting material. A light-emitting layer of the quantum dot light-emitting display panel may include quantum dots, quantum rods, or the like. Hereinafter, the display panel DP will be described as an organic light-emitting display panel.

The display panel DP may include a plurality of pixels PX, a plurality of scan lines SL1-SLm, a plurality of data lines DL1-DLn, a plurality of emission lines EL1-ELm, first and second control lines CSL1 and CSL2, first and second power lines PLL1 and PLL2, connection lines CNL, and a plurality of pads PD. Here, m and n are natural numbers.

The pixels PX may be disposed in the display region DA. A scan driver SDV and an emission driver EDV may be disposed in the non-display region NDA next (adjacent) to the respective long sides of the display panel DP. A data driver DDV may be disposed in the non-display region NDA next (adjacent) to any one short side among the short sides of the display panel DP. When seen in a plan view, the data driver DDV may be next (adjacent) to a lower end of the display panel DP.

The scan lines SL1-SLm may extend in the first direction DR1 and be connected to the pixels PX and the scan driver SDV. The data lines DL1-DLn may extend in the second direction DR2 and be connected to the pixels PX and the data driver DDV. The emission lines EL1-ELm may extend in the first direction DR1 and be connected to the pixels PX and the emission driver EDV.

The first power line PLL1 may extend in the second direction DR2 and be disposed in the non-display region NDA. The first power line PLL1 may be disposed between the display region DA and the emission driver EDV, or without being limited thereto, may be disposed between the display region DA and the scan driver SDV.

The connection lines CNL may extend in the first direction DR1 and be arranged in the second direction DR2. The connection lines CNL may be connected to the first power line PLL1 and the pixels PX. A first voltage may be applied to the pixels PX through the first power line PLL1 and the connection lines CNL connected to each other.

The second power line PLL2 may be disposed in the non-display region NDA. The second power line PLL2 may extend along the long sides of the display panel DP and another one short side of the display panel DP where the data driver DDV is not disposed. The second power line PLL2 may be disposed outside the scan driver SDV and the emission driver EDV.

Although not illustrated, the second power line PLL2 may extend toward the display region DA and be connected to the pixels PX. A second voltage having a lower voltage level than the first voltage may be applied to the pixels PX through the second power line PLL2.

The first control line CSL1 may be connected to the scan driver SDV, and when seen in a plan view, may extend toward the lower end of the display panel DP. The second control line CSL2 may be connected to the emission driver EDV, and when seen in a plan view, may extend toward the lower end of the display panel DP. The data driver DDV may be disposed between the first control line CSL1 and the second control line CSL2.

The pads PD may be disposed on the display panel DP. The pads PD may be more next (adjacent) to the lower end of the display panel DP than the data driver DDV. The data driver DDV, the first power line PLL1, the second power line PLL2, the first control line CSL1, and the second control line CSL2 may be connected to the pads PD. The data lines DL1-DLn may be connected to the data driver DDV and the data driver DDV may be connected to the pads PD corresponding to the data lines DL1-DLn.

Light-emitting elements of the display panel DP may be formed by the plurality of cell regions CA illustrated in FIG. 5. Unit regions corresponding to the display panel DP may be defined in a target substrate M-SUB. The light-emitting elements may be formed in the unit regions, and then the unit regions may be cut. As a result, the display panel DP illustrated in FIG. 19 may be manufactured.

Although not illustrated, a timing controller for controlling the operations of the scan driver SDV, the data driver DDV, and the emission driver EDV and a voltage generator for generating the first and second voltages may be disposed on a printed circuit board. The timing controller and the voltage generator may be connected to the corresponding pads PD through the printed circuit board.

The scan driver SDV may generate a plurality of scan signals, and the scan signals may be applied to the pixels PX through the scan lines SL1-SLm. The data driver DDV may generate a plurality of data voltages, and the data voltages may be applied to the pixels PX through the data lines DL1-DLn. The emission driver EDV may generate a plurality of emission signals, and the emission signals may be applied to the pixels PX through the emission lines EL1-ELm.

The pixels PX may receive data voltages in response to scan signals. The pixels PX may display images by emitting, in response to emission signals, light with a brightness corresponding to the data voltages. The emission time of the pixels PX may be controlled by the emission signals.

Aforementioned lines may include the data lines DL1-DLn. The pads connected to the aforementioned lines may include the pads PD illustrated in FIG. 19. The display panel DP in which light-emitting layers of the pixels PX are not formed may be defined as the aforementioned target substrate M-SUB.

FIG. 20 is a view that illustrates a cross-sectional view of one pixel illustrated in FIG. 19.

A pixel PX may be disposed on a base substrate BL, and may include a transistor TR and a light-emitting element OLED. The transistors TR and the light-emitting elements OLED of the pixels PX may be connected to the aforementioned data lines DL1-DLn and the first and second power lines PLL1 and PLL2. The transistors TR and the light-emitting elements OLED of the pixels PX may be connected to the pads PD through the data lines DL1-DLn and the first and second power lines PLL1 and PLL2.

The light-emitting element OLED may include a first electrode AE, a second electrode CE, a hole control layer HCL, an electron control layer ECL, and a light-emitting layer EML. The first electrode AE may be an anode electrode, and the second electrode CE may be a cathode electrode.

The transistor TR and the light-emitting element OLED may be disposed on the base substrate BL. One transistor TR is illustrated in an embodiment, but substantially, the pixel PX may include a plurality of transistors and at least one capacitor for operating the light-emitting element OLED.

A display region DA may include a light-emitting region PA corresponding to the pixel PX and a non-light-emitting region NPA around the light-emitting region PA. The light-emitting element OLED may be disposed in the light-emitting region PA.

The base substrate BL may include a flexible plastic substrate. In an embodiment, the base substrate BL may include a transparent polyimide (“PI”), for example. A buffer layer BFL may be disposed on the base substrate BL and the buffer layer BFL may be an inorganic layer.

A semiconductor pattern may be disposed on the buffer layer BFL. The semiconductor pattern may include polysilicon. However, the inventive concept is not limited thereto, and the semiconductor pattern may include amorphous silicon or metal oxide.

The semiconductor pattern may be doped with an N-type dopant or a P-type dopant. The semiconductor pattern may include a heavily doped region and a lightly doped region. The conductivity of the heavily doped region is greater than the lightly doped region, and may substantially serve as a source electrode and a drain electrode of a transistor TR. The lightly doped region may substantially correspond to an active (or a channel) of a transistor.

A source S-D, an active A-D, and a drain D-D of the transistor TR may be formed from the semiconductor pattern. A first insulation layer 10 may be disposed on the semiconductor pattern. A gate G-D of the transistor TR may be disposed on the first insulation layer 10. A second insulation layer 20 may be disposed on the gate G. A third insulation layer 30 may be disposed on the second insulation layer 20. In an embodiment, an auxiliary electrode EE may be disposed on the second insulation layer 20.

A connection electrode CNE may be disposed between the transistor TR and the light-emitting element OLED and connect the transistor TR and the light-emitting element OLED. The connection electrode CNE may include a first connection electrode CNE1 and a second connection electrode CNE2.

The first connection electrode CNE1 may be disposed on the third insulation layer 30 and connected to a signal line SCL (or the drain D-D) through a first contact hole CNT-1 defined in the first to third insulation layers 10 to 30. A fourth insulation layer 40 may be disposed on the first connection electrode CNE1. A fifth insulation layer 50 may be disposed on the fourth insulation layer 40.

The second connection electrode CNE2 may be disposed on the fifth insulation layer 50. The second connection electrode CNE2 may be connected to the first connection electrode CNE1 through a second contact hole CNT-2 defined in the fourth insulation layer 40. The first insulation layer 10 to the fifth insulation layer 50 may be inorganic layers or organic layers.

The first electrode AE may be disposed on the fifth insulation layer 50. The first electrode AE may be connected to the second connection electrode CNE2 through a third contact hole CNT-3 defined in the fifth insulation layer 50. A pixel-defining film PDL which exposes a portion of the first electrode AE may be disposed on the first electrode AE and the fifth insulation layer 50. An opening PX_OP for exposing a portion of the first electrode AE may be defined in the pixel-defining film PDL.

The hole control layer HCL may be disposed on the first electrode AE and the pixel-defining film PDL. The hole control layer HCL may be disposed in common in the light-emitting region PA and the non-light-emitting region NPA. The hole control layer HCL may include a hole transport layer and a hole injection layer.

The light-emitting layer EML may be disposed on the hole control layer HCL. The light-emitting layer EML may be disposed in a region corresponding to the opening PX_OP. The light-emitting layer EML may include an organic material and/or an inorganic material. The light-emitting layer EML may generate any one among red light, green light, and blue light.

The electron control layer ECL may be disposed on the light-emitting layer EML and the hole control layer HCL. The electron control layer ECL may be disposed in common in the light-emitting region PA and the non-light-emitting region NPA. The electron control layer ECL may include an electron transport layer and an electron injection layer.

The second electrode CE may be disposed on the electron control layer ECL. The second electrode CE may be disposed in common in the pixels PX. Layers from the buffer layer BFL to the light-emitting element OLED may be defined as a pixel layer PXL.

A thin-film encapsulation layer TFE may be disposed on the light-emitting element OLED. The thin-film encapsulation layer TFE may be disposed on the second electrode CE and cover the pixel PX. The thin-film encapsulation layer TFE may include at least two inorganic layers and an organic layer between the inorganic layers. An inorganic layer may protect the pixel PX from moisture/oxygen. An organic layer may protect the pixel PX from foreign matters such as dust particles.

The first voltage may be applied to the first electrode AE through the transistor TR, and the second voltage which has a lower voltage level than the first voltage may be applied to the second electrode CE. Holes and electrons injected to the light-emitting layer EML are combined to form excitons, and the light-emitting element OLED may emit light as the excitons transit to a ground state.

FIG. 21 is a view for describing a deposition process by the deposition device illustrated in FIG. 4.

Referring to FIG. 21, a structure “from the base substrate BL to the hole control layer HCL” may correspond to the “target substrate M-SUB” illustrated in FIG. 4.

A mask assembly MA (refer to FIG. 4) may be disposed to face the target substrate M-SUB. However, for the convenience of explanation, FIG. 20 illustrates, in an embodiment, a portion of the first pattern part PT1 and one pattern opening P-OP defined in the first pattern part PT1 included in the mask assembly MA (refer to FIG. 4).

The mask assembly MA (refer to FIG. 4) may be disposed next (adjacent) to the target substrate M-SUB. The deposition material DM may pass through the pattern opening P-OP and be provided onto the target substrate M-SUB. A light-emitting layer EML may be formed on the target substrate M-SUB by the deposition material DM.

A mask assembly according to the inventive concept may significantly reduce a warpage phenomenon. Accordingly, during a deposition process, adhesion of the mask assembly to a target substrate may be improved, and the reliability of the deposition process using the mask assembly may be improved.

A mask assembly manufacturing method according to the inventive concept makes it possible to simply manufacture a mask assembly with which a warpage phenomenon is reduced. Accordingly, manufacturing costs and time for the mask assembly may be reduced.

In the above, description has been made with reference to embodiments, but those skilled in the art or those of ordinary skill in the relevant technical field may understand that various modifications and changes may be made to the inventive concept within the scope not departing from the spirit and the technology scope of the inventive concept described in the claims to be described later. Therefore, the technical scope of the inventive concept is not limited to the contents described in the detailed description of the specification, but should be determined by the claims.

What is claimed is:

1. A mask assembly comprising:
a wafer which includes a top surface and a rear surface and in which cell openings penetrating the top surface and the rear surface are defined;
an upper layer which is disposed on the top surface of the wafer and in which upper openings respectively overlapping the cell openings are defined;
first pattern parts disposed on the upper layer, spaced apart from each other in a plan view, and respectively overlapping the cell openings;
a first lower layer disposed on the rear surface of the wafer; and
a second lower layer disposed under the first lower layer,
wherein pattern openings are defined in each of the first pattern parts.

2. The mask assembly of claim 1, wherein the upper layer comprises one among silicon oxide (SiOx), silicon nitride (SiNx), silicon oxynitride (SiON), and metal nitride, and
the first pattern parts comprise another one.

3. The mask assembly of claim 1, wherein at least a portion of a top surface of the upper layer is exposed from the first pattern parts, and
the wafer comprises silicon.

4. The mask assembly of claim 1, wherein in the plan view, a separation distance between the first pattern parts next to each other is about 2 millimeters to about 5 millimeters.

5. The mask assembly of claim 1, wherein the wafer has a circular shape in the plan view,
the mask assembly further comprises dummy pattern parts disposed on the upper layer and spaced apart from the first pattern parts in the plan view, and
the dummy pattern parts next to each other are disposed symmetrically to each other in the plan view with respect to a virtual line crossing a center of the wafer.

6. The mask assembly of claim 5, wherein the dummy pattern parts and the first pattern parts comprise a same material and the dummy pattern parts do not overlap the cell openings.

7. The mask assembly of claim 1, further comprising (2-1)-th pattern parts disposed on the upper layer and extending in a first direction, and (2-2)-th pattern parts disposed on the upper layer and extending in a second direction crossing the first direction,
wherein the first pattern parts are respectively disposed between the (2-1)-th pattern parts next to each other and the (2-2)-th pattern parts next to each other.

8. The mask assembly of claim 7, wherein the (2-1)-th pattern parts and the (2-2)-th pattern parts are spaced apart from the first pattern parts by intervals.

9. The mask assembly of claim 1, further comprising (2-1)-th pattern parts disposed between the first pattern parts next to each other in a first direction, and arranged along a second direction crossing the first direction, and
(2-2)-th pattern parts disposed between the first pattern parts next to each other in the second direction, and arranged along the first direction.

10. The mask assembly of claim 9, further comprising (2-3)-th pattern parts disposed between the (2-1)-th pattern parts next to each other and the (2-2)-th pattern parts next to each other, and having an ‘X’ shape.

11. The mask assembly of claim 1, further comprising:
(2-1)-th pattern parts extending in a first direction and disposed between the first pattern parts next to each other in a second direction crossing the first direction; and
(2-2)-th pattern parts extending in the second direction and spaced apart from each other in the second direction with the (2-1)-th pattern parts respectively interposed therebetween.

12. The mask assembly of claim 1, wherein first lower openings respectively overlapping the cell openings in the plan view are defined in the first lower layer, and
second lower openings respectively overlapping the first lower openings in the plan view are defined in the second lower layer.

13. The mask assembly of claim 1, wherein each of the cell openings has a width becoming smaller toward the rear surface of the wafer and the top surface of the wafer.

14. The mask assembly of claim 1, wherein the pattern openings overlap the cell openings, and
ends of the first pattern parts overlap the upper layer in the plan view.

15. The mask assembly of claim 1, wherein the top surface of the wafer makes direct contact with the upper layer, and
a top surface of the upper layer makes direct contact with a first pattern part of the first pattern parts.

16. A method of manufacturing a mask assembly, the method comprising:
providing a wafer;
forming an upper layer on a top surface of the wafer and forming a first lower layer on a rear surface of the wafer;
forming a pattern layer on a top surface of the upper layer and forming a second lower layer on a rear surface of the first lower layer;
etching the pattern layer and forming a pattern part including first pattern parts which are, in a plan view, spaced apart from each other and in which pattern openings are defined;
etching the first and second lower layers and defining lower openings in the first and second lower layers; and
etching the wafer toward the top surface from the rear surface and defining cell openings respectively overlapping the first pattern parts in the wafer.

17. The method of claim 16, wherein the forming the upper layer and the forming the first lower layer are performed at the same time through a single process, and
the forming the pattern layer and the forming the second lower layer are performed at the same time through a single process.

18. The method of claim 16, wherein the defining the lower openings comprises:
etching the second lower layer toward a top surface from a rear surface and defining a second lower opening in the second lower layer; and
etching the first lower layer toward a top surface from the rear surface and defining a first lower opening in the first lower layer.

19. The method of claim 16, further including etching the pattern layer and forming a second pattern part spaced apart from the first pattern parts in the plan view,
wherein the forming the first pattern parts and the forming the second pattern part are performed at the same time through a single process.

20. The method of claim 16, wherein the defining the cell openings is performed through wet etching, and
each of the cell openings has a width becoming smaller toward the rear surface of the wafer and the top surface of the wafer.
